(19) United States
(12) Patent Application Publication
(10) Pub. No.: US 2008/0121845 A1
(43) Pub. Date: May 29, 2008

(54) Oxetane composition, associated method and article

(75) Inventors: Ryan Christopher Mills, Rexford, NY (US); Slawomir Rubinsztajn, Ballston Spa, NY (US); John Robert Campbell, Putnam Station, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company, Schenectady, NY (US)

(21) Appl. No.: 11/503,523

(22) Filed: Aug. 11, 2006

(51) Int. Cl. H01L 23/24; H01L 21/56; C08G 77/14; C08G 65/00

(52) U.S. Cl. 252/500; 257/778; 438/127; 528/417; 528/27; 257/E23.14

(57) ABSTRACT

An underfill composition including a polymer precursor is provided. The polymer precursor includes 4 or more pendant oxetane functional groups. The underfill composition includes greater than about 20 weight percent of the polymeric precursor. Associated article and method are also provided.

### BACKGROUND

1. Technical Field

The invention includes embodiments that relate to a composition. The invention includes embodiments that relate to method of using the composition and related article.

2. Discussion of Art

Capillary underfill resins may fill a gap between a silicon chip and a substrate to improve the fatigue life of solder bumps in an assembly. While capillary underfill resins may improve reliability, additional process steps may be needed for their use that may reduce manufacturing productivity. Some underfill applications may include no-flow underfill (NFU) and wafer-level underfill (WLU). The NFU may require a viscosity suitable for a flow stage. The WLU may require a solid resin system (B-staged underfill) after application to the wafer so as to not interfere with the dicing of the wafer into individual chips. The needs of the WLU may be a balance of B-stage properties with reflow capability and final cure properties. To achieve a solid resin system for WLU a solvent-based resin system or a partially advanced polymerizable resin system may be used. A solvent-based resin system may result in void formation due to inefficient solvent removal. A partially advanced polymerizable resin may result in premature curing of the resin and reduced reflow characteristics.

In some applications, underfill resin systems may be required that cure at a higher temperature than at which the solder bump reflows. Solder bumps may include eutectic lead-tin alloys or may be lead free (for example, polymeric interconnects). In the case of lead-free interconnects, solder reflow temperatures may be greater than 175 degrees Celsius. Epoxy-and cyanate ester-based underfill systems may not be stable at the high temperatures and may form volatile products.

It may be desirable to have a solid resin system for use as a WLU with properties and/or characteristics that differ from those resin systems currently available. It may be desirable to have a method of forming a solid resin system for use as a WLU with properties and/or characteristics that differ from those methods currently available.

### BRIEF DESCRIPTION

In one embodiment, an underfill composition is provided. The underfill composition includes a polymer precursor. The polymer precursor includes 4 or more pendant oxetane functional groups. The underfill composition includes greater than about 20 weight percent of the polymeric precursor.

In one embodiment, an article is provided. The article includes, a chip, a substrate, and underfill material disposed between the chip and the substrate. The underfill material includes a filled composition. The filled composition includes a filler and a polymer precursor. The polymer precursor includes 4 or more pendant oxetane functional groups. The underfill material includes greater than about 20 weight percent of the polymeric precursor.

In one embodiment, a method is provided. The method includes disposing an underfill material in contact with a surface of a chip. The underfill material includes a filled composition. The filled composition includes a filler and a polymer precursor. The polymer precursor includes 4 or more pendant oxetane functional groups. The underfill material includes greater than about 20 weight percent of the polymeric precursor. The method includes contacting the chip with a substrate to form an electronic assembly; heating the electronic assembly to a temperature sufficient to cure the underfill material; and curing the underfill material.

### BRIEF DESCRIPTION OF DRAWING FIGURES

FIG. 1 is a differential scanning calorimetry thermogram of a composition in accordance with one embodiment of the invention.

FIG. 2 is a differential scanning calorimetry thermogram of a composition in accordance with one embodiment of the invention.

### DETAILED DESCRIPTION

The invention includes embodiments that relate to a composition. The invention includes embodiments that relate to method of using the composition and related article.

In the following specification and the claims which follow, reference will be made to a number of terms have the following meanings. The singular forms “a”, “an” and “the” include plural referents unless the context clearly dictates otherwise. Approximating language, as used herein throughout the specification and claims, may be applied to modify any quantitative representation that could permissibly vary without resulting in a change in the basic function to which it is related. Accordingly, a value modified by a term such as “about” is not to be limited to the precise value specified. In some instances, the approximating language may correspond to the precision of an instrument for measuring the value. Similarly, “free” may be used in combination with a term, and may include an insubstantial number, or trace amounts, while still being considered free of the modified term. For example, free of solvent or solvent-free, and like terms and phrases, may refer to an instance in which a significant portion, some, or all of the solvent has been removed from a solvated material.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable, or suitable. For example, in some circumstances an event or capacity can be expected, while in other circumstances the event or capacity cannot occur—this distinction is captured by the terms “may” and “may be”.

B-stage refers to a cure stage of a material in which a partially cured, and/or solvent free, material may be rubbery, solid, or tack free and may have partially solubility in solvent. B-staging a material, and related terms and phrases, may include at least partially solidifying a material by one or more of heating for a determined amount of time, optionally under vacuum, to remove some or all of a solvent; advancing a cure or cross-linking a curable underfill layer material from an uncured state to a partially, but not completely, cured state; or curing a first of a plurality of curable materials in a mixture of curable materials having differing cure properties. Tack free may refer to a surface that does not possess pressure sensitive adhesive properties at about room temperature. By one measure, a tack-free surface will not adhere or stick to a finger placed lightly in contact therewith at about 25 degrees Celsius, or will have a Dahlquist criterion indicating a storage modulus (G′) of more than about 3×10⁵ Pascal (measured at 10 radians/second at room temperature). Solid refers to a property such that a material does flow perceptibly under moderate stress, or has a definite capacity for resisting one or more forces (e.g., compression or tension) that may otherwise tend to deform it. In one aspect, under ordinary conditions a solid may retain a definite size and shape. Stability, as used herein in the specification and claims, refers to the ratio of viscosity of a mixture of the solid and the curable material measured initially after mixing, and measured again after a period of time, e.g., one week or two weeks. Oxetane includes the class of heterocyclic compounds having a four-membered ring with three carbon atoms and one oxygen atom.

An underfill composition according to one embodiment, of the invention includes a polymer precursor. The polymer precursor includes four or more pendant oxetane functional groups; and the polymer precursor includes greater than about 20 weight percent of the underfill composition. A polymer precursor may include monomeric species, oligomeric species, mixtures of monomeric species, mixtures of oligomeric species, polymeric species, mixtures of polymeric species, partially-crosslinked species, mixtures of partially-crosslinked crosslinked species, or mixtures of two or more of the foregoing. Reference to polymer precursor herein is to oxetane-functionalized polymer precursor unless context indicates otherwise.

The number of oxetane functional groups in the polymer precursor may determine the curing temperature and kinetics of curing of the polymeric precursors. In one embodiment, the polymer precursor has four or more oxetane functional groups. In one embodiment, the polymer precursor has six or more oxetane functional groups. In one embodiment, the polymer precursor has eight or more oxetane functional groups.

A polymer precursor may have an organic or an inorganic backbone. A suitable organic material may have only carbon-carbon linkages (for example, olefins) or carbon-heteroatom-carbon linkages (for example, ethers, esters and the like) in the main chain. Suitable examples of organic materials as polymer precursors may include one or more of olefin-derived polymer precursors, for example, ethylene, propylene, and their mixtures; methylpentane-derived polymer precursors, for example, butadiene, isoprene, and their mixtures; polymer precursors of unsaturated carboxylic acids and their functional derivatives, for example, acrylics such as alkyl acrylates, alkyl methacrylate, acrylamides, acrylonitrile, and acrylic acid; alkenylaromatic polymer precursors, for example styrene, alpha-methylstyrene, vinyltoluene, and rubber-modified styrenes; amides, for example, nylon-6, nylon-6,6, nylon-1,1, and nylon-1,2; esters, such as, alkylene dicarboxylates, especially ethylene terephthalate, 1,4-butylene terephthalate, trimethylene terephthalate, ethylene naphthalate, butylene naphthalate, cyclohexanedimethanol terephthalate, cyclohexanedimethanol-co-ethylene terephthalate, and 1,4-cyclohexanedimethyl-1,4-cyclohexanedicarboxylate and alkylene arenedioates; carbonates; estercarbonates; sulfones; imides; arylene sulfides; sulfide sulfones; and ethers such as arylene ethers, phenylene ethers, ethersulfones, etherimides, etherketones, etheretherketones; or blends, homopolymers, or copolymers thereof

A suitable inorganic backbone for a polymer precursor may include main chain linkages other than that of carbon-carbon linkages or carbon-heteroatom-carbon linkages, for example, silicon-silicon linkages in silanes, silicon-oxygen-silicon linkages in siloxanes, phosphorous-nitrogen-phosphorous linkages in phosphazenes, and the like.

In one embodiment, a polymer precursor may include silicon-oxygen-silicon linkages, such as in siloxanes. Siloxanes may also be referred to as organosiloxanes, where organosiloxanes include silicon-oxygen-silicon linkages and one or more of the silicon atoms is substituted with an organic group. Suitable siloxanes may include linear siloxanes, cyclic siloxanes, branched siloxanes, partially crosslinked siloxanes, or silsesquioxanes. In one embodiment, the polymer precursor may include structural units of formula (I):

MₐM_{b}′D_{c}D_{d}′TₑT_{f}′Q_{g} (I)

wherein the subscripts “a”, “b”, c “d”, “e”, “f” and “g” are independently zero or a positive integer, and the sum of integers “b”, “d”, and “f” is greater than or equal to 4; and wherein M has the formula:

R¹R²R³SiO_{1/2}, (II)

M′ has the formula:

(Z)R⁴R⁵SiO_{1/2}, (III)

D has the formula:

R⁶R⁷SiO_{2/2}, (IV)

D′ has the formula:

(Z)R⁸SiO_{2/2}, (V)

T has the formula:

R⁹SiO_{3/2}, (VI)

T′ has the formula:

(Z)SiO_{3/2}, (VII)

and Q has the formula:

SiO_{4/2}, (VIII)

wherein R¹ to R⁹ are independently at each occurrence an aliphatic radical, an aromatic radical, a cycloaliphatic radical, an acrylate, a urethane, a urea, a melamine, a phenol, an isocyanate, or a cyanate ester, and Z includes an oxetane functional group. In one embodiment, a polymer precursor having formula (I) includes oxetane functional groups and R¹ to R⁹ are independently at each occurrence an aliphatic radical, an aromatic radical, or a cycloaliphatic radical. Aliphatic radical, aromatic radical and cycloaliphatic radical are defined as follows:

An aliphatic radical is an organic radical having at least one carbon atom, a valence of at least one, and is a linear or branched bonded array of atoms. Aliphatic radicals may include heteroatoms such as nitrogen, sulfur, silicon, selenium and oxygen or may be composed exclusively of carbon and hydrogen. Aliphatic radical may include a wide range of functional groups such as alkyl groups, alkenyl groups, alkynyl groups, halo alkyl groups, conjugated dienyl groups, alcohol groups, ether groups, aldehyde groups, ketone groups, carboxylic acid groups, acyl groups (for example, carboxylic acid derivatives such as esters and amides), amine groups, nitro groups and the like. For example, the 4-methylpent-1-yl radical is a C₆ aliphatic radical comprising a methyl group, the methyl group being a functional group, which is an alkyl group. Similarly, the 4-nitrobut-1-yl group is a C₄ aliphatic radical comprising a nitro group, the nitro group being a functional group. An aliphatic radical may be a haloalkyl group that includes one or more halogen atoms, which may be the same or different. Halogen atoms include, for example; fluorine, chlorine, bromine, and iodine. Aliphatic radicals having one or more halogen atoms include the alkyl halides: trifluoromethyl, bromodifluoromethyl, chlorodifluoromethyl, hexafluoroisopropylidene, chloromethyl, difluorovinylidene, trichloromethyl, bromodichloromethyl, bromoethyl, 2-bromotrimethylene (e.g., —CH₂CHBrCH₂—), and the like. Further examples of aliphatic radicals include allyl, aminocarbonyl (—CONH₂), carbonyl, dicyanoisopropylidene —CH₂C(CN)₂CH₂—), methyl (—CH₃), methylene (—CH₂—), ethyl, ethylene, formyl (—CHO), hexyl, hexamethylene, hydroxymethyl (—CH₂OH), mercaptomethyl (—CH₂SH), methylthio (—SCH₃), methylthiomethyl (—CH₂SCH₃), methoxy, methoxycarbonyl (CH₃OCO—), nitromethyl (—CH₂NO₂), thiocarbonyl, trimethylsilyl ((CH₃)₃Si—), t-butyldimethylsilyl, trimethoxysilylpropyl ((CH₃O)₃SiCH₂CH₂CH₂—), vinyl, vinylidene, and the like. By way of further example, a “C₁-C₃₀ aliphatic radical” contains at least one but no more than 30 carbon atoms. A methyl group (CH₃—) is an example of a C₁ aliphatic radical. A decyl group (CH₃(CH₂)₉—) is an example of a C₁₀ aliphatic radical.

An aromatic radical is a bonded array of atoms having a valence of at least one and having at least one bonded array that forms an aromatic group. This bonded array can include heteroatoms such as nitrogen, sulfur, selenium, silicon and oxygen, or can be composed exclusively of carbon and hydrogen. Suitable aromatic radicals may include phenyl, pyridyl, furanyl, thienyl, naphthyl, phenylene, and biphenyl radicals. The aromatic group may be a cyclic structure having 4n+2 “delocalized” electrons where “n” is an integer equal to 1 or greater, as illustrated by phenyl groups (n=1), thienyl groups (n=1), furanyl groups (n=1), naphthyl groups (n=2), azulenyl groups (n=2), anthracenyl groups (n=3) and the like. The aromatic radical also may include non-aromatic components. For example, a benzyl group may be an aromatic radical, which includes a phenyl ring (the aromatic group) and a methylene group (the non-aromatic component). Similarly a tetrahydronaphthyl radical is an aromatic radical comprising an aromatic group (C₆H₃) fused to a non-aromatic component —(CH₂)₄—. An aromatic radical may include one or more functional groups, such as alkyl groups, alkenyl groups, alkynyl groups, haloalkyl groups, haloaromatic groups, conjugated dienyl groups, alcohol groups, ether groups, aldehyde groups, ketone groups, carboxylic acid groups, acyl groups (for example carboxylic acid derivatives such as esters and amides), amine groups, nitro groups, and the like. For example, the 4-methylphenyl radical is a C₇ aromatic radical comprising a methyl group, the methyl group being a functional group, which is an alkyl group. Similarly, the 2-nitrophenyl group is a C6 aromatic radical comprising a nitro group, the nitro group being a functional group. Aromatic radicals include halogenated aromatic radicals such as trifluoromethylphenyl, hexafluoroisopropylidenebis(4-phen-1-yloxy) (—OPhC(CF₃)₂PhO—), chloromethylphenyl, 3-trifluorovinyl-2-thienyl, 3-trichloromethyl phen-1-yl (3-CCl₃Ph-), 4-(3-bromoprop-1-yl)phen-1-yl (BrCH₂CH₂CH₂Ph-), and the like. Further examples of aromatic radicals include 4-allyloxyphen-1-oxy, 4-aminophen-1-yl (H₂NPh-), 3-aminocarbonylphen-1-yl (NH₂COPh-), 4-benzoylphen-1-yl, dicyanoisopropylidenebis(4-phen-1-yloxy) (—OPhC(CN)₂PhO—), 3-methylphen-1-yl, methylene bis(phen-4-yloxy) (—OPhCH₂PhO—), 2-ethylphen-1-yl, phenylethenyl, 3-formyl-2-thienyl, 2-hexyl-5-furanyl; hexamethylene-1,6-bis(phen-4-yloxy) (—OPh(CH₂)₆PhO—), 4-hydroxymethyl phen-1-yl (4-HOCH₂Ph-), 4-mercaptomethyl phen-1-yl (4-HSCH₂Ph-), 4-methylthio phen-1-yl (4-CH₃SPh-), 3-methoxy phen-1-yl, 2-methoxycarbonyl phen-1-yloxy (e.g., methyl salicyl), 2-nitromethyl phen-1-yl (-PhCH₂NO₂), 3-trimethylsilylphen-1-yl, 4-t-butyldimethylsilylphenl-1-yl, 4-vinylphen-1-yl, vinylidenebis(phenyl), and the like. The term “a C₃-C₃₀ aromatic radical” includes aromatic radicals containing at least three but no more than 30 carbon atoms. The aromatic radical 1-imidazolyl (C₃H₂N₂—) represents a C₃ aromatic radical. The benzyl radical (C₇H₇—) represents a C₇ aromatic radical.

A cycloaliphatic radical is a radical having a valence of at least one, and having a bonded array of atoms that is cyclic but which is not aromatic. A cycloaliphatic radical may include one or more non-cyclic components. For example, a cyclohexylmethyl group (C₆H₁₁CH₂—) is a cycloaliphatic radical, which includes a cyclohexyl ring (the array of atoms, which is cyclic but which is not aromatic) and a methylene group (the noncyclic component). The cycloaliphatic radical may include heteroatoms such as nitrogen, sulfur, selenium, silicon and oxygen, or may be composed exclusively of carbon and hydrogen. A cycloaliphatic radical may include one or more functional groups, such as alkyl groups, alkenyl groups, alkynyl groups, halo alkyl groups, conjugated dienyl groups, alcohol groups, ether groups, aldehyde groups, ketone groups, carboxylic acid groups, acyl groups (for example carboxylic acid derivatives such as esters and amides), amine groups, nitro groups and the like. For example, the 4-methylcyclopent-1-yl radical is a C₆ cycloaliphatic radical comprising a methyl group, the methyl group being a functional group, which is an alkyl group. Similarly, the 2-nitrocyclobut-1-yl radical is a C₄ cycloaliphatic radical comprising a nitro group, the nitro group being a functional group. A cycloaliphatic radical may include one or more halogen atoms, which may be the same or different. Halogen atoms include, for example, fluorine, chlorine, bromine, and iodine. Cycloaliphatic radicals having one or more halogen atoms include 2-trifluoro methylcyclohex-1-yl; 4-bromodifluoro methyl cyclo oct-1-yl; 2-chlorodifluoro methyl cyclohex-1-yl; hexafluoro isopropylidene 2,2-bis(cyclohex-4-yl) (—C₆H₁₀C(CF₃)₂C₆H₁₀O—); 2-chloromethyl cyclohex-1-yl; or 3-difluoro methylene cyclohex-1-yl. Further examples of cycloaliphatic radicals include 4-allyloxy cyclohex-1-yl, 4-amino cyclohex-1-yl (H₂NC₆H₁₀—), 4-amino carbonyl cyclopent-1-yl (NH₂COC₅H₈—), 4-acetyloxycyclohex-1-yl, 2,2-dicyanoisopropylidene bis (cyclohex-4-yloxy) (—OC₆H₁₀C(CN)₂C₆H₁₀O—), 3-methylcyclohex-1-yl, methylene bis(cyclohex-4-yloxy) (—OC₆H₁₀CH₂C₆H₁₀O—), 1-ethyl cyclobut-1-yl, cyclopropyl ethenyl, 3-formyl-2-tetrahydrofuranyl, 2-hexyl-5-tetrahydrofuranyl; hexamethylene-1,6-bis(cyclohex-4-yloxy) (—OC₆H₁₀(CH₂)₆C₆H₁₀O—); 4-hydroxymethyl cyclohex-1-yl (4-HOCH₂C₆H₁₀—), 4-mercaptomethyl cyclohex-1-yl (4-HSCH₂C₆H₁₀—), 4-methylthio cyclohex-1-yl (4-CH₃SC₆H₁₀—), 4-methoxycyclohex-1-yl, 2-methoxy carbonyl cyclohex-1-yloxy (2-CH₃OCOC₆H₁₀O—), 4-nitromethyl cyclohex-1-yl (NO₂CH₂C₆H₁₀—), 3-trimethylsilyl cyclohex-1-yl, 2-t-butyldimethyl silylcyclopent-1-yl, 4-trimethoxy silylethyl cyclohex-1-yl (e.g. (CH₃O)₃SiCH₂CH₂C₆H₁₀O—), 4-vinyl cyclohexen-1-yl, vinylidene bis(cyclohexyl), and the like. The term “a C₃-C₃₀ cycloaliphatic radical” includes cycloaliphatic radicals containing at least three but no more than 10 carbon atoms. The cycloaliphatic radical 2-tetrahydrofuranyl (C₄H₇O—) represents a C₄ cycloaliphatic radical. The cyclohexylmethyl radical (C₆H₁₁CH₂—) represents a C₇ cycloaliphatic radical.

Suitable siloxanes may include low molecular weight species such as monomers or oligomers or may include high molecular weight species such as polymers. In one embodiment, the sum of subscripts in structure of formula (I) may be in a range of from about 4 to about 10, from about 10 to about 20, from about 20 to about 50, from about 50 to about 100, from 100 to about 200, from about 200 to about 500, or from about 500 to about 1000. In one embodiment, the sum of subscripts in structure of formula (I) may be in a range of greater than about 1000, greater than about 2000, greater than about 5000, or greater than about 10000. The siloxanes included in structure (I) may have a broad molecular weight distribution and the subscripts “a”, “b”, “c”, “d”, “e”, “f” and “g” stated above designate the average composition only. Here and throughout the specification and claims, range limitations may be combined and/or interchanged. Such ranges as identified include all the sub-ranges contained therein unless context or language indicates otherwise.

In one embodiment, a polymer precursor may have a number average molecular weight in a range of from about 50 grams per mole to about 100 grams per mole, from about 100 grams per mole to about 200 grams per mole, from about 200 grams per mole to about 500 grams per mole, from about 500 grams per mole to about 1000 grams per mole, from about 1000 grams per mole to about 2500 grams per mole, from about 2500 grams per mole to about 5000 grams per mole, from about 5000 grams per mole to about 10000 grams per mole, from about 10000 grams per mole to about 25000 grams per mole, from about 25000 grams per mole to about 50000 grams per mole, or from about 50000 grams per mole to about 100000 grams per mole. In one embodiment, a polymer precursor may have a number average molecular weight in a range of greater than about 100000 grams per mole.

Suitable examples of structural units of formula (I) include oxetane-functionalized cyclic siloxanes, oxetane-functionalized linear siloxanes, oxetane-functionalized branched siloxanes, or oxetane-functionalized silsesquioxanes. In one embodiment, a polymer precursor includes one or more cyclic siloxanes having formula (IX)

D_{c}D_{d}′ (IX)

wherein subscript “c”, “d”, D and D′ are the same as defined hereinabove. In one embodiment, R⁶, R⁷ and R⁸ are aliphatic radicals that may be the same or different. In one embodiment, the cyclic siloxane (IX) includes one or more of tetraoxetanyl dimethylcyclotrisiloxane, hexaoxetanyl cyclotrisiloxane, tetraoxetanyl tetramethylcyclotetrasiloxane, hexaoxetanyl dimethylcyclotetrasiloxane, octaoxetanyl cyclotetrasiloxane, tetraoxetanyl hexamethylcyclopentasiloxane, tetraoxetanyl octamethylcyclohexasiloxane, or tetraoxetanyl tetravinyl cyclotetrasiloxane.

In one embodiment, a polymer precursor includes one or more linear siloxanes having formula (X)

MₐM_{b}′D_{c}D_{d}′ (X)

wherein subscripts “a”, “b”, “c”, “d”, M, M′, D and D′ are the same as defined hereinabove. In one embodiment, the linear siloxane (X) includes one or more of tetraoxetanyl dimethyldisiloxane, tetraoxetanyl tetramethyltrisiloxane, tetraoxetanyl hexamethyltetrasiloxane, tetraoxetanyl octamethylpentasiloxane, or tetraoxetanyl-decamethylhexasiloxane. Cyclic and linear siloxanes of different molecular weight and with different functionalities may be commercially available from Gelest Inc., Morrisville Pa., USA.

In one embodiment, a polymer precursor includes one or more silsesquioxanes having formula (XI)

TₑT_{f}′ (XI)

wherein subscripts “e”, “f”, T, and T′ are the same as defined hereinabove. Suitable examples of oxetane-functionalized silsesquioxanes may include one or more of structures of formulae (XII) to (XV):

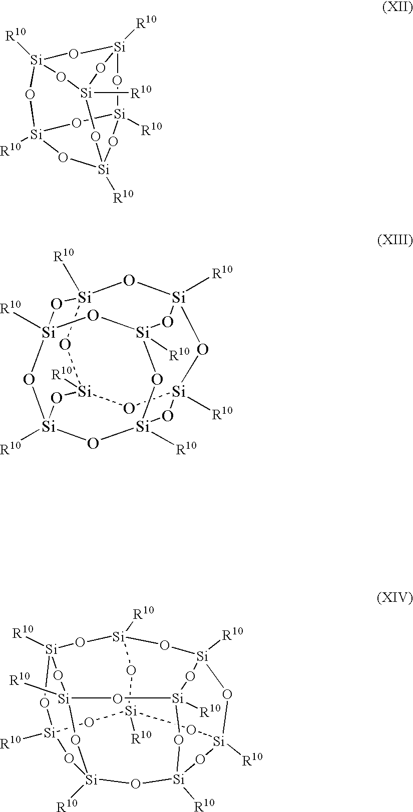

wherein R¹⁰ includes an oxetane functional group. In one embodiment, an oxetane functional group may include structural units of formula (XV):

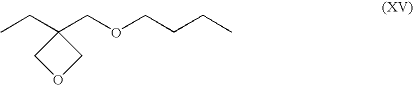

In one embodiment, a polymer precursor may include partially hydrolyzed structures of silsesquioxanes of formula (XI). Suitable partially hydrolyzed silsesquioxanes may include one or more structures of formulae (XVI), (XVII), (XVIII) or (XIX).

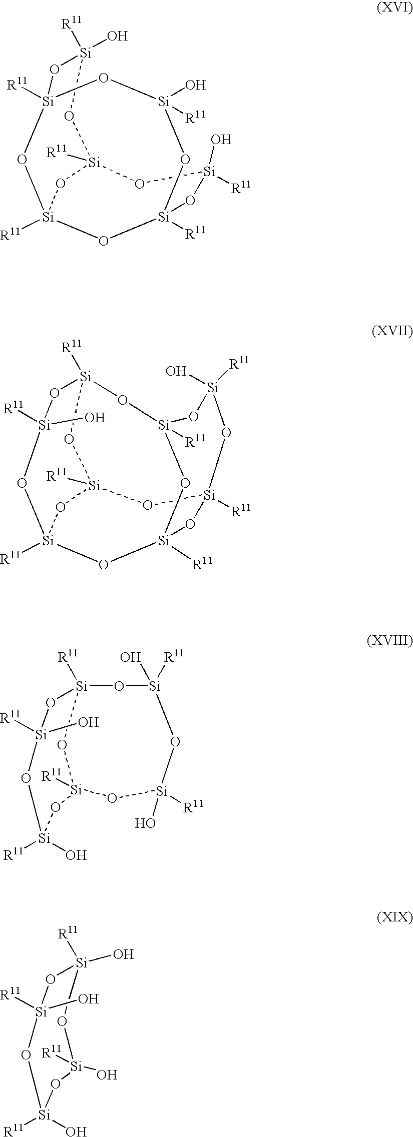

wherein R¹¹ includes an oxetane functional group. In one embodiment, an oxetane functional group may include structural units of formula (XV) as described hereinabove.

In one embodiment, an oxetane-functionalized polymer precursor may be synthesized by functionalizing the polymer precursor backbone with one or more oxetane functional groups. Functionalizations may be carried by reaction of suitable reactive groups on the polymer precursor backbone with a compound having an oxetane functional group. Suitable reactive groups may include one or more of amine, carboxyl, hydroxyl, cyano, halogen, vinyl, allyl, vinyl, silicon hydride, and the like. A polymer precursor backbone may react with an oxetane functional group to form linkages such as amide, ester, ether, carbonate, carbamate, saturated alkanes, and the like. In one embodiment, a polymer precursor may be prepared by a hydrosilylation reaction between a polymer precursor backbone having —SiH functional group and a compound having an oxetane functional group and an allyl functional group. In one embodiment, a polymer precursor may be prepared by reaction of a polymer precursor backbone having a hydroxyl functional group and a halogenated oxetanyl-functionalized compound. In one embodiment, a polymer precursor includes oxetane functional groups linked to the backbone via ether linkages.

Suitable oxetane functional groups can be the reaction product of one or more of 3-bromomethyl-3-hydroxymethyl oxetane; 3,3-bis-(ethoxymethyl) oxetane; 3,3-bis-(chloromethyl) oxetane; 3,3-bis-(methoxymethyl) oxetane; 3,3-bis-(fluoromethyl) oxetane; 3-hydroxymethyl-3-methyl oxetane; 3,3-bis-(acetoxymethyl) oxetane; 3,3-bis-(hydroxy methyl) oxetane; 3-octoxy methyl-3-methyl oxetane; 3-chloromethyl-3-methyl oxetane; 3-azidomethyl-3-methyl oxetane; 3,3-bis-(iodomethyl) oxetane; 3-iodomethyl-3-methyl oxetane; 3-propyno methyl-3-methyl oxetane; 3-nitrato methyl-3-methyl oxetane; 3-difluoro amino methyl-3-methyl oxetane; 3,3-bis-(difluoro amino methyl) oxetane; 3,3-bis-(methyl nitrato methyl) oxetane; 3-methyl nitrato methyl-3-methyl oxetane; 3,3-bis-(azidomethyl) oxetane; or 3-ethyl-3-((2-ethylhexyloxy) methyl) oxetane.

As noted, in one embodiment, a polymer precursor can be the reaction product of a halogenated and oxetane-functionalized compound. In some embodiments, the polymer precursor may include unreacted halogen groups that may provide properties such as flame retardancy to the underfill composition. In one embodiment, the underfill composition includes halogen in an amount in a range of from about 0.1 weight percent to about 0.5 weight percent of the underfill composition, from about 0.5 weight percent to about 1 weight percent of the underfill composition, from about 1 weight percent to about 2 weight percent of the underfill composition, from about 2 weight percent to about 5 weight percent of the underfill composition, or from about 5 weight percent to about 10 weight percent of the underfill composition.

A polymer precursor may also include other reactive functional groups along with the oxetane functional groups. Suitable reactive functional groups may participate in a chemical reaction (for example polymerization or crosslinking) when exposed to one or more of thermal energy, electromagnetic radiation, or chemical reagents. In one embodiment, the polymer precursor may include reactive functional groups (other than oxetane groups) that may participate in a chemical reaction via free radical polymerization, atom transfer radical polymerization, ring-opening polymerization, ring-opening metathesis polymerization, anionic polymerization, or cationic polymerization. In one embodiment, the polymer precursor may include one or more of acrylate, urethane, urea, melamine, phenol, isocyanate, cyanate ester, or other suitable reactive functional groups. A polymer precursor may include a plurality of functional groups that may be chemically different from each other, for example, acrylate and oxetane functional groups. In one embodiment, the polymer precursor and the underfill composition is free of epoxy. In one embodiment, the polymer precursor and the underfill composition is free of cyanate ester. In one embodiment, the polymer precursor and the underfill composition includes cyanate ester along with oxetane. In one embodiment, the polymer precursor includes only oxetane functional groups.

In one embodiment, the polymer precursor may be present in an amount in a range of from about 10 weight percent to about 20 weight percent of the underfill composition, from about 20 weight percent to about 25 weight percent of the underfill composition, from about 25 weight percent to about 30 weight percent of the underfill composition, or from about 30 weight percent to about 40 weight percent of the underfill composition. In one embodiment, the polymer precursor may be present in an amount in a range of from about 40 weight percent to about 45 weight percent of the underfill composition, from about 45 weight percent to about 50 weight percent of the underfill composition, from about 50 weight percent to about 55 weight percent of the underfill composition, or from about 55 weight percent to about 60 weight percent of the underfill composition. In one embodiment, the polymer precursor may be present in an amount in a range of greater than about 60 weight percent of the underfill composition.

In one embodiment, the underfill composition further includes a alcohol and an anhydride. The alcohol includes one or more hydroxyl functional groups, and the anhydride includes one or more cyclic anhydride functional groups. Cyclic anhydride functional groups may include a closed ring structure having an anhydride group and having a ring number of 4 or more carbon atoms.

In one embodiment, the anhydride responds to a first stimulus by reacting with the alcohol to cure. In one embodiment, the first stimulus may include exposure to energy of a type selected from the group consisting of thermal energy or electromagnetic radiation. Thermal energy may include application of heat to the first alcohol and the anhydride. Electromagnetic radiation may include ultraviolet, electron beam, or microwave radiation.

In one embodiment, the oxetane functional groups in the polymer precursor respond to a second stimulus that is different from the first stimulus to cure. In one embodiment, the two stimuli may be completely different, for example, the alcohol and the anhydride may be cured by heating to a particular temperature at which the oxetane may not cure, followed by curing of the oxetane by e-beam radiation. In one embodiment, the two stimuli may include the same type of energy (thermal or electromagnetic), however, the degree or amount of energy applied may be different. For example, the alcohol and the anhydride may cure by heating to a first temperature (T₁) and the oxetane may only cure at a higher temperature (T₂), and not at T₁.

Curing may refer to a reaction resulting in polymerization, cross-linking, or both polymerization and cross-linking of a material having one or more reactive groups (for example, hydroxyl groups in an alcohol or oxetane groups in the polymer precursor). Cured may refer to a material having reactive groups wherein more than about 50 percent of the reactive groups have reacted, or alternatively a percent conversion of the material is in a range of greater than about 50 percent. Percent conversation may refer to a percentage of the total number of reacted groups to the total number of reactive groups.

In one embodiment, a percent conversion of the alcohol and the anhydride is greater than about 50 percent at the first temperature, and a percent conversion of the polymer precursor is less than about 10 percent at the first temperature, after a time period of greater than about 1 hour. In one embodiment, a percent conversion of the alcohol and the anhydride is greater than about 50 percent at the first temperature, and a percent conversion of the polymer precursor is less than about 20 percent at the first temperature, after a time period of greater than about 1 hour. In one embodiment, a percent conversion of the alcohol and the anhydride is greater than about 60 percent at the first temperature, and a percent conversion of the polymer precursor is less than about 10 percent at the first temperature, after a time period of greater than about 1 hour. In one embodiment, a percent conversion of the alcohol and the anhydride is greater than about 60 percent at the first temperature, and a percent conversion of the polymer precursor is less than about 20 percent at the first temperature, after a time period of greater than about 1 hour. In one embodiment, a percent conversion of the alcohol and the anhydride is greater than about 75 percent at the first temperature, and a percent conversion of the polymer precursor is less than about 10 percent at the first temperature, after a time period of greater than about 1 hour. In one embodiment, a percent conversion of the alcohol and the anhydride is greater than about 75 percent at the first temperature, and a percent conversion of the polymer precursor is less than about 20 percent at the first temperature, after a time period of greater than about 1 hour. In one embodiment, a percent conversion of the alcohol and the anhydride is greater than about 50 percent at the first temperature, and a percent conversion of the polymer precursor is less than about 10 percent at the first temperature, after a time period of greater than about 2 hours. In one embodiment, a percent conversion of the alcohol and the anhydride is greater than about 50 percent at the first temperature, and a percent conversion of the polymer precursor is less than about 10 percent at the first temperature, after a time period of greater than about 5 hours.

A percent conversion of the alcohol and the anhydride may depend on one or more of a ratio of the number of hydroxyl groups to the cyclic anhydride groups, reactivity of the alcohol, or reactivity of the anhydride. In one embodiment, a ratio of the number of hydroxyl groups to the cyclic anhydride groups is in a range of less than about 1/3. In one embodiment, a ratio of the number of hydroxyl groups to the cyclic anhydride groups is in a range of from about 1/3 to about 1/2, from about 1/2 to about 2/3, from about 2/3 to about 1/1, from about 3/2, from about 3/2 to about 2/1, from about 2/1 to about 8/3, or from about 8/3 to about 3/1. In one embodiment, a ratio of the number of hydroxyl groups to the cyclic anhydride groups is in a range of greater than about 3/1.

Suitable alcohols may include one or more hydroxy-functionalized aliphatic, cycloaliphatic, or aromatic materials. In one embodiment, the average number of hydroxyl groups per alcohol molecule may in a range of about 1. In one embodiment, the average number of hydroxyl groups per alcohol molecule may in a range of about 2. In one embodiment, the average number of hydroxyl groups per alcohol molecule may in a range of about 3. In one embodiment, the average number of hydroxyl groups per alcohol molecule may in a range of greater than about 3.

In one embodiment, the alcohol may include an aliphatic material. The aliphatic material may be straight chain, branched or cycloaliphatic. Suitable aliphatic alcohols may include one or more of ethylene glycol; propylene glycol; 1,4-butane diol; 2,2-dimethyl-1,3-propane diol; 2-ethyl 2-methyl, 1,3-propane diol; 1,3- and 1,5-pentane diol; dipropylene glycol; 2-methyl-1,5-pentane diol; 1,6-hexane diol; dimethanol decalin, dimethanol bicyclo octane; 1,4-cyclohexane dimethanol; triethylene glycol; 1,10-decane diol; biphenol, bisphenol, glycerol, trimethylol propane; trimethylol ethane; pentaerythritol; sorbitol; or polyether glycol; and derivatives thereof.

In one embodiment, the alcohol may include hydroxyl-functionalized aromatic materials. Suitable hydroxy-functionalized aromatic materials may include structural units represented by the formula (XX):

HO-G-OH (XX)

wherein G may be a divalent aromatic radical. In one embodiment, at least about 50 percent of the total number of G groups may be aromatic organic radicals and the balance thereof may be aliphatic, cycloaliphatic, or aromatic organic radicals. In one embodiment, G may include structural units represented by the formula (XXI):

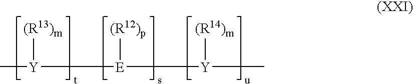

wherein Y represents an aromatic radical such as phenylene, biphenylene, or naphthylene. E may be a bond or an aliphatic radical. In embodiments, where E is a bond, the alcohol is a bisphenol. In one embodiment, E may be an aliphatic radical, such as alkylene or alkylidene radicals. Suitable alkylene or alkylidene radical may include methylene, ethylene, ethylidene, propylene, propylidene, isopropylidene, butylene, butylidene, isobutylidene, amylene, amylidene, and isoamylidene. When E is an alkylene or alkylidene radical, it also may consist of two or more alkylene or alkylidene radicals connected by a moiety different from alkylene or alkylidene, such as an aromatic linkage; a tertiary amino linkage; an ether linkage; a carbonyl linkage; a silicon-containing linkage such as silane or siloxy; or a sulfur-containing linkage such as sulfide, sulfoxide, or sulfone; or a phosphorus-containing linkage such as phosphinyl or phosphonyl. In one embodiment, E may be a cycloaliphatic radical. Suitable cycloaliphatic radicals may include cyclopentylidene, cyclohexylidene, 3,3,5-trimethylcyclohexylidene, methylcyclo-hexylidene, 2-{2.2.1}-bicycloheptylidene, neopentylidene, cyclopentadecylidene, cyclododecylidene, and adamantylidene. R¹² is independently at each occurrence a hydrogen, a monovalent aliphatic radical, a monovalent cycloaliphatic radical, or a monovalent aromatic radical such as alkyl, aryl, aralkyl, alkaryl, cycloalkyl, or bicycloalkyl. R¹³ and R¹⁴ are independently at each occurrence a halogen, such as fluorine, bromine, chlorine, and iodine; a tertiary nitrogen group such as dimethylamino; a group such as R¹² described herein above, or an alkoxy group such as OR¹⁵ wherein R¹⁵ may be an aliphatic, cycloaliphatic or aromatic radical. The subscript “m” represents any integer from and including zero through the number of positions on Y available for substitution; “p” represents an integer from and including zero through the number of positions on E available for substitution; “t” represents an integer equal to at least one; “s” may be either zero or one; and “u” represents any integer including zero.

In the structure of formula (XXI), when more than one R¹³ or R¹⁴ substituents may be present, the substituents may be the same or different. For example, the R¹² substituents may be a combination of differing halogens. The R¹² substituents may be the same or different if more than one R¹² substituents may be present. Where “s” may be zero and “u” may be not zero, the aromatic rings may be directly joined with no intervening alkylidene or other bridge. The positions of the hydroxyl groups, R¹³ or R¹⁴ radicals on the aromatic nuclear residues Y may be varied in the ortho, meta, or para positions and the groupings may be in vicinal, asymmetrical or symmetrical relationship, where two or more ring carbon atoms of the hydrocarbon residue may be substituted with hydroxyl groups, R¹³ or R¹⁴ radicals.

Suitable hydroxy-functionalized aromatic compounds may include one or more of 1,1-bis(4-hydroxyphenyl)cyclopentane; 2,2-bis(3-allyl-4-hydroxyphenyl)propane; 2,2-bis(2-t-butyl-4-hydroxy-5-methylphenyl)propane; 2,2-bis(3-t-butyl-4-hydroxy-6-methylphenyl)propane; 2,2-bis(3-t-butyl-4-hydroxy-6-methylphenyl)butane; 1,3-bis[4-hydroxyphenyl-1-(1-methylethylidine)]benzene; 1,4-bis[4-hydroxyphenyl-1-(1-methylethylidine)]benzene; 1,3-bis[3-t-butyl-4-hydroxy-6-methylphenyl-1-(1-methylethylidine)]benzene; 1,4-bis[3-t-butyl-4-hydroxy-6-methylphenyl-1-(1-methylethylidine)]benzene; 4,4′-biphenol; 2,2′,6,8-tetramethyl-3,3′,5,5′-tetrabromo-4,4′-biphenol; 2,2′,6,6′-tetramethyl-3,3′,5-tribromo-4,4′-biphenol; 1,1-bis(4-hydroxyphenyl)-2,2,2-trichloroethane; 2,2-bis(4-hydroxyphenyl-1,1,1,3,3,3-hexafluoropropane); 1,1-bis(4-hydroxyphenyl)-1-cyanoethane; 1,1-bis(4-hydroxyphenyl)dicyanomethane; 1,1-bis(4-hydroxyphenyl)-1-cyano-1-phenylmethane; 2,2-bis(3-methyl-4-hydroxyphenyl)propane; 1,1-bis(4-hydroxyphenyl)norbornane; 9,9-bis(4-hydroxyphenyl)fluorene; 3,3-bis(4-hydroxyphenyl)phthalide; 1,2-bis(4-hydroxyphenyl)ethane; 1,3-bis(4-hydroxyphenyl)propenone; bis(4-hydroxyphenyl) sulfide; 4,4′-oxydiphenol; 4,4-bis(4-hydroxyphenyl)pentanoic acid; 4,4-bis(3,5-dimethyl-4-hydroxyphenyl)pentanoic acid; 2,2-bis(4-hydroxyphenyl) acetic acid; 2,4′-dihydroxydiphenylmethane; 2-bis(2-hydroxyphenyl)methane; bis(4-hydroxyphenyl)methane; bis(4-hydroxy-5-nitrophenyl)methane; bis(4-hydroxy-2,6-dimethyl-3-methoxyphenyl)methane; 1,1-bis(4-hydroxyphenyl)ethane; 1,1-bis(4-hydroxy-2-chlorophenyl)ethane; 2,2-bis(4-hydroxyphenyl)propane (bisphenol-A); 1,1-bis(4-hydroxyphenyl)propane; 2,2-bis(3-chloro-4-hydroxyphenyl)propane; 2,2-bis(3-bromo-4-hydroxyphenyl)propane; 2,2-bis(4-hydroxy-3-methylphenyl)propane; 2,2-bis(4-hydroxy-3-isopropylphenyl)propane; 2,2-bis(3-t-butyl-4-hydroxyphenyl)propane; 2,2-bis(3-phenyl-4-hydroxyphenyl)propane; 2,2-bis(3,5-dichloro-4-hydroxyphenyl)propane; 2,2-bis(3,5-dibromo-4-hydroxyphenyl)propane; 2,2-bis(3,5-dimethyl-4-hydroxyphenyl)propane; 2,2-bis(3-chloro-4-hydroxy-5-methylphenyl)propane; 2,2-bis(3-bromo-4-hydroxy-5-methylphenyl)propane; 2,2-bis(3-chloro-4-hydroxy-5-isopropylphenyl)propane; 2,2-bis(3-bromo-4-hydroxy-5-isopropylphenyl)propane; 2,2-bis(3-t-butyl-5-chloro-4-hydroxyphenyl)propane; 2,2-bis(3-bromo-5-t-butyl-4-hydroxyphenyl)propane; 2,2-bis(3-chloro-5-phenyl-4-hydroxyphenyl)propane; 2,2-bis(3-bromo-5-phenyl-4-hydroxyphenyl)propane; 2,2-bis(3,5-disopropyl-4-hydroxyphenyl)propane; 2,2-bis(3,5-di-t-butyl-4-hydroxyphenyl)propane; 2,2-bis(3,5-diphenyl-4-hydroxyphenyl)propane; 2,2-bis(4 hydroxy-2,3,5,6-tetrachlorophenyl)propane; 2,2-bis(4-hydroxy-2,3,5,6-tetrabromophenyl)propane; 2,2-bis(4-hydroxy-2,3,5,6-tetramethylphenyl)propane; 2,2-bis(2,6-dichloro-3,5-dimethyl-4-hydroxyphenyl)propane; 2,2-bis(2,6-dibromo-3,5-dimethyl-4-hydroxyphenyl)propane; 2,2-bis(4-hydroxy-3-ethylphenyl)propane; 2,2-bis(4-hydroxy-3,5-dimethylphenyl)propane; 2,2-bis(3,5,3′,5′-tetrachloro-4,4′-dihydroxyphenyl)propane; 1,1-bis(4-hydroxyphenyl)cyclohexylmethane; 2,2-bis(4-hydroxyphenyl)-1-phenylpropane; 1,1-bis(4-hydroxyphenyl)cyclohexane; 1,1-bis(3-chloro-4-hydroxyphenyl)cyclohexane; 1,1-bis(3-bromo-4-hydroxyphenyl)cyclohexane; 1,1-bis(4-hydroxy-3-methylphenyl)cyclohexane; 1,1-bis(4-hydroxy-3-isopropylphenyl)cyclohexane; 1,1-bis(3-t-butyl-4-hydroxyphenyl)cyclohexane; 1,1-bis(3-phenyl-4-hydroxyphenyl)cyclohexane; 1,1-bis(3,5-dichloro-4-hydroxyphenyl)cyclohexane; 1,1-bis(3,5-dibromo-4-hydroxyphenyl)cyclohexane; 1,1-bis(3,5-dimethyl-4-hydroxyphenyl)cyclohexane; 4,4′-[1-methyl-4-(1-methyl-ethyl)-1,3-cyclohexandiyl]bisphenol (1,3 BHPM); 4-[1-[3-(4-hydroxyphenyl)-4-methylcyclohexyl]-1-methyl-ethyl]-phenol (2,8 BHPM); 3,8-dihydroxy-5a,10b-diphenylcoumarano-2′,3′,2,3-coumarane (DCBP); 2-phenyl-3,3-bis(4-hydroxyphenyl)phthalimidine; 1,1-bis(3-chloro-4-hydroxy-5-methylphenyl)cyclohexane; 1,1-bis(3-bromo-4-hydroxy-5-methylphenyl)cyclohexane; 1,1-bis(3-chloro-4-hydroxy-5-isopropylphenyl)cyclohexane; 1,1-bis(3-bromo-4-hydroxy-5-isopropylphenyl)cyclohexane; 1,1-bis(3-t-butyl-5-chloro-4-hydroxyphenyl)cyclohexane; 1,1-bis(3-bromo-5-t-butyl-4-hydroxyphenyl)cyclohexane; 1,1-bis(3-chloro-5-phenyl-4-hydroxyphenyl)cyclohexane; 1,1-bis(3-bromo-5-phenyl-4-hydroxyphenyl)cyclohexane; 1,1-bis(3,5-disopropyl-4-hydroxyphenyl)cyclohexane; 1,1-bis(3,5-di-t-butyl-4-hydroxyphenyl)cyclohexane; 1,1-bis(3,5-diphenyl-4-hydroxyphenyl)cyclohexane; 1,1-bis(4-hydroxy-2,3,5,6-tetrachlorophenyl)cyclohexane; 1,1-bis(4-hydroxy-2,3,5,6-tetrabromophenyl)cyclohexane; 1,1-bis(4-hydroxy-2,3,5,6-tetramethylphenyl)cyclohexane; 1,1-bis(2,6-dichloro-3,5-dimethyl-4-hydroxyphenyl)cyclohexane; 1,1-bis(2,6-dibromo-3,5-dimethyl-4-hydroxyphenyl)cyclohexane; 1,1-bis(4-hydroxyphenyl)-3,3,5-trimethylcyclohexane; 1,1-bis(3-chloro-4-hydroxyphenyl)-3,3,5-trimethylcyclohexane; 1,1-bis(3-bromo-4-hydroxyphenyl)-3,3,5-trimethylcyclohexane; 1,1-bis(4-hydroxy-3-methylphenyl)-3,3,5-trimethylcyclohexane; 1,1-bis(4-hydroxy-3-isopropylphenyl)-3,3,5-trimethylcyclohexane; 1,1-bis(3-t-butyl-4-hydroxyphenyl)-3,3,5-trimethylcyclohexane; 1,1-bis(3-phenyl-4-hydroxyphenyl)-3,3,5-trimethylcyclohexane; 1,1-bis(3,5-dichloro-4-hydroxyphenyl)-3,3,5-trimethylcyclohexane; 1,1-bis(3,5-dibromo-4-hydroxyphenyl)-3,3,5-trimethylcyclohexane; 1,1-bis(3,5-dimethyl-4-hydroxyphenyl)-3,3,5-trimethylcyclohexane; 1,1-bis(3-chloro-4-hydroxy-5-methylphenyl)-3,3,5-trimethylcyclohexane; 1,1-bis(3-bromo-4-hydroxy-5-methylphenyl)-3,3,5-trimethylcyclohexane; 1,1-bis(3-chloro-4-hydroxy-5-isopropylphenyl)-3,3,5-trimethylcyclohexane; 1,1-bis(3-bromo-4-hydroxy-5-isopropylphenyl)-3,3,5-trimethylcyclohexane; 1,1-bis(3-t-butyl-5-chloro-4-hydroxyphenyl)-3,3,5-trimethylcyclohexane; 1,1-bis(3-bromo-5-t-butyl-4-hydroxyphenyl)-3,3,5-trimethylcyclohexane; bis(3-chloro-5-phenyl-4-hydroxyphenyl)-3,3,5-trimethylcyclohexane; 1,1-bis(3-bromo-5-phenyl-4-hydroxyphenyl)-3,3,5-trimethylcyclohexane; 1,1-bis(3,5-disopropyl-4-hydroxyphenyl)-3,3,5-trimethylcyclohexane; 1,1-bis(3,5-di-t-butyl-4-hydroxyphenyl)-3,3,5-trimethylcyclohexane; 1,1-bis(3,5-diphenyl-4-hydroxyphenyl)-3,3,5-trimethylcyclohexane; 1,1-bis(4-hydroxy-2,3,5,6-tetrachlorophenyl)-3,3,5-trimethylcyclohexane; 1,1-bis(4-hydroxy-2,3,5,6-tetrabromophenyl)-3,3,5-trimethylcyclohexane; 1,1-bis(4-hydroxy-2,3,5,6-tetramethylphenyl)-3,3,5-trimethylcyclohexane; 1,1-bis(2,6-dichloro-3,5-dimethyl-4-hydroxyphenyl)-3,3,5-trimethylcyclohexane; 1,1-bis(2,6-dibromo-3,5-dimethyl-4-hydroxyphenyl)-3,3,5-trimethylcyclohexane; 4,4-bis(4-hydroxyphenyl)heptane; 1,1-bis(4-hydroxyphenyl)decane; 1,1-bis(4-hydroxyphenyl)cyclododecane; 1,1-bis(3,5-dimethyl-4-hydroxyphenyl)cyclododecane; 4,4′ dihydroxy-1,1-biphenyl; 4,4′-dihydroxy-3,3′-dimethyl-1,1-biphenyl; 4,4′-dihydroxy-3,3′-dioctyl-1,1-biphenyl; 4,4′-(3,3,5-trimethylcyclohexylidene)diphenol; 4,4′-bis(3,5-dimethyl)diphenol; 4,4′-dihydroxydiphenylether; 4,4′-dihydroxydiphenylthioether; 1,3-bis(2-(4-hydroxyphenyl)-2-propyl)benzene; 1,3-bis(2-(4-hydroxy-3-methylphenyl)-2-propyl)benzene; 1,4-bis(2-(4-hydroxyphenyl)-2-propyl)benzene; 1,4-bis(2-(4 hydroxy-3-methylphenyl)-2-propyl)benzene; 2,4′-dihydroxyphenyl sulfone; 4,4′-dihydroxydiphenylsulfone (BPS); bis(4-hydroxyphenyl)methane; 2,6-dihydroxy naphthalene; hydroquinone; resorcinol; C₁₋₃ alkyl-substituted resorcinols; 3-(4-hydroxyphenyl)-1,1,3-trimethylindan-5-ol; 1-(4-hydroxyphenyl)-1,3,3-trimethylindan-5-ol; 4,4-dihydroxydiphenyl ether; 4,4-dihydroxy-3,3-dichlorodiphenylether; 4,4-dihydroxy-2,5-dihydroxydiphenyl ether; 4,4-thiodiphenol; 2,2,2′,2′-tetrahydro-3,3,3′,3′-tetramethyl-1,1′-spirobi[1H-indene]-6,6′-diol; and mixtures thereof.

In one embodiment, the alcohol may be present in an amount in a range of from about 5 weight percent to about 10 weight percent of the underfill composition, from about 10 weight percent to about 20 weight percent of the underfill composition, from about 20 weight percent to about 30 weight percent of the underfill composition, or from about 30 weight percent to about 40 weight percent of the underfill composition. In one embodiment, the alcohol may be present in an amount in a range of from about 40 weight percent to about 50 weight percent of the underfill composition, from about 50 weight percent to about 60 weight percent of the underfill composition, from about 60 weight percent to about 70 weight percent of the underfill composition, or from about 70 weight percent to about 80 weight percent of the underfill composition. In one embodiment, the alcohol may be present in an amount in a range of greater than about 80 weight percent of the underfill composition.

An anhydride may include a chemical compound having one or more cyclic anhydride functional groups. Suitable anhydrides may include one or more cyclic anhydride functionalized organic or inorganic materials. Suitable organic anhydrides may include one or more of phthalic anhydride; phthalic dianhydride; hexahydro phthalic anhydride; hexahydro phthalic dianhydride; 4-nitrophthalic anhydride; 4-nitrophthalic dianhydride; methyl-hexahydro phthalic anhydride; methyl-hexahydro phthalic dianhydride; naphthalene tetracarboxylic acid dianhydride; naphthalic anhydride; tetrahydro phthalic anhydride; tetrahydro phthalic dianhydride; pyromellitic dianhydride; cyclohexane dicarboxylic anhydride; 2-cyclohexane dicarboxylic anhydride; bicyclo(2.2.1) heptane-2,3-dicarboxylic anhydride; bicyclo (2.2.1) hept-5-ene-2,3-dicarboxylic anhydride, methylbicyclo(2.2.1) hept-5-ene-2,3-dicarboxylic anhydride; maleic anhydride; glutaric anhydride; 2-methyl glutaric anhydride; 2,2-dimethyl glutaric anhydride; hexafluoro glutaric acid anhydride; 2-phenylglutaric anhydride; 3,3-tetramethylene glutaric anhydride; itaconic anhydride; tetrapropenylsuccinic anhydride; octadecyl succinic anhydride; 2- or n-octenyl succinic anhydride; dodecenylsuccinic anhydride; dodecenyl succinic anhydride; or derivatives thereof.

Suitable inorganic anhydrides may include structural units of formula (XXII):

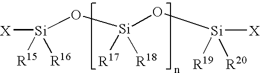

### (XXII)

where “n” is an integer in a range of from about 0 to about 50, X includes cyclic anhydride structural units, and each R¹⁵, R¹⁶, R¹⁷, R¹⁸, R¹⁹ and R²⁰ are independently at each occurrence an aliphatic radical, a cycloaliphatic radical, or an aromatic radical. In one embodiment, “n” is in a range of from about 1 to about 10, from about 10 to about 25, from about 25 to about 40, from about 40 to about 50, or greater than about

In one embodiment, R¹⁵, R¹⁶, R¹⁷, R¹⁸, R¹⁹ and R²⁰ may include a halogen group, such as, fluorine or chlorine group. In one embodiment, one or more of R¹⁵, R¹⁶, R¹⁷, R¹⁸, R¹⁹ and R²⁰ may include a methyl, ethyl, propyl, 3,3,3-trifluoropropyl, isopropyl, or phenyl radical.

In one embodiment, X in formula (XXII) may include structural units of formula (XXIII):

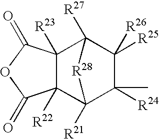

### (XXIII)

wherein R²¹—R²⁷ may be hydrogen, a halogen, an aliphatic radical, a cycloaliphatic radical or an aromatic radical. R²⁸ may be oxygen or C—R²⁹, wherein R²⁹ is any two selected from hydrogen, a halogen, an aliphatic radical, a cycloaliphatic radical or an aromatic radical.

In one embodiment, the anhydride may be present in an amount in a range of from about 5 weight percent to about 10 weight percent of the underfill composition, from about 10 weight percent to about 20 weight percent of the underfill composition, from about 20 weight percent to about 30 weight percent of the underfill composition, or from about 30 weight percent to about 40 weight percent of the underfill composition. In one embodiment, the anhydride may be present in an amount in a range of from about 40 weight percent to about 50 weight percent of the underfill composition, from about 50 weight percent to about 60 weight percent of the underfill composition, from about 60 weight percent to about 70 weight percent of the underfill composition, or from about 70 weight percent to about 80 weight percent of the underfill composition. In one embodiment, the anhydride may be present in an amount in a range of greater than about 80 weight percent of the underfill composition.

A curing temperature may depend on one or more of the chemistry of the reactive groups (for example, reactivity of alcohol and the anhydride), curing conditions, or presence or absence of curing agents, for example, catalysts. In one embodiment, the alcohol and the anhydride may cure at a first temperature (T₁) in a range of less than about 50 degrees Celsius. In one embodiment, the alcohol and the anhydride may cure at a first temperature (T₁) in a range of from about 50 degrees Celsius to about 75 degrees Celsius, from about 75 degrees Celsius to about 100 degrees Celsius, or from about 100 degrees Celsius to about 150 degrees Celsius. In one embodiment, the alcohol and the anhydride may cure at a first temperature (T₁) in a range of greater than about 150 degrees Celsius. In one embodiment, the alcohol and the anhydride specifically cures at a first temperature in a range of from about 50 degrees Celsius to about 150 degrees Celsius.

In one embodiment, the polymer precursor may cure at a second temperature (T₂), which is higher than the first temperature (T₁). In embodiment, the difference between the second temperature and the first temperature may be in a range of greater than about 100 degrees Celsius. In embodiment, the difference between the second temperature and the first temperature may be in a range of greater than about 75 degrees Celsius. In embodiment, the difference between the second temperature and the first temperature may be in a range of greater than about 50 degrees Celsius. In embodiment, the difference between the second temperature and the first temperature may be in a range of greater than about 25 degrees Celsius.

In one embodiment, the polymer precursor may cure only at a second temperature (T₂) in a range of greater than about 150 degrees Celsius. In one embodiment, the polymer precursor may cure at a second temperature (T₂) in a range of from about 150 degrees Celsius to about 175 degrees Celsius, from about 175 degrees Celsius to about 200 degrees Celsius, from about 200 degrees Celsius to about 250 degrees Celsius, from about 250 degrees Celsius to about 275 degrees Celsius, or from about 275 degrees Celsius to about 300 degrees Celsius. In one embodiment, the polymer precursor may cure at a second temperature (T₂) in a range of greater than about 300 degrees Celsius. In one embodiment, the polymer precursor specifically cures at a second temperature in a range of from about 150 degrees Celsius to about 300 degrees Celsius.

In one embodiment, the alcohol and the anhydride may cure at the first temperature to a B-stage. A B-stage is a cure stage in which a partially cured material may be rubbery, solid, tack free, or may have partially solubility in a solvent. In one embodiment, the alcohol and the anhydride may cure to a B-stage by one or more of increasing the number average molecular weight of the composition (for example, during polymerization), by forming interpenetrating polymeric networks, or by chemically crosslinking. In certain embodiments, alcohol and the anhydride may cure by a combination of two or more of the foregoing, for example, the curing reaction may include an increase in number average molecular weight as well as formation of crosslinks. In one embodiment, the alcohol and the anhydride may cure to a B-stage by increasing the number average molecular weight the composition. In one embodiment, an anhydride may react with an alcohol at the first temperature to increase the number average molecular weight of the composition.

In one embodiment, the underfill composition may include a catalyst. The catalyst may catalyze (accelerate) a curing reaction of the polymer precursor in response to the second temperature and not in response to the first temperature. The catalyst may catalyze the curing reaction by a free radical mechanism, atom transfer mechanism, ring-opening mechanism, ring-opening metathesis mechanism, anionic mechanism, or cationic mechanism.

In one embodiment, the catalyst includes a cationic initiator that catalyzes a curing reaction of the oxetane functional groups. A suitable cationic initiator may include one or more of an onium salt, a Lewis acid, or an alkylation agent. Suitable Lewis acid catalyst may include copper boron acetoacetate, cobalt boron acetoacetate, or both include copper boron acetoacetate and cobalt boron acetoacetate. Suitable alkylation agents may include arylsulfonate esters, for example, methyl-p-toluene sulfonate or methyl trifluoromethanesulfonate. Suitable onium salts may include one or more of an iodonium salt, an oxonium salt, a sulfonium salt, a sulfoxonium salt, a phosphonium salt, a metal boron acetoacetae, a tris(pentaflurophenyl) boron; or arylsulfonate ester. In one embodiment, a suitable cationic initiator may include bisaryliodonium salts, triarylsulphonium salts, or tetraaryl phosphonium salts. A suitable bisaryliodonium salt may include one or more of bis(dodecylphenyl) iodonium hexafluoro antimonate; (octyloxyphenyl, phenyl) iodonium hexafluoro antimonate; or bisaryliodonium tetrakis(pentafluoro phenyl) borate. A suitable tetraaryl phosphonium salt may include tetraphenylphosphonium bromide.

In one embodiment, the catalyst includes a free radical initiator that catalyzes a curing reaction of the oxetane functional groups. A suitable free-radical generating compound may include one or more aromatic pinacols, benzoinalkyl ethers, organic peroxides, and combinations of two or more thereof. In one embodiment, the catalyst may include an onium salt along with a free radical generator. The free radical generating compound may facilitate decomposition of onium salt at a relatively lower temperature.

Other suitable cure catalysts may include one or more of amines, alkyl-substituted imidazole, imidazolium salts, phosphines, metal salts such as aluminum acetyl acetonate (Al(acac)3), or salts of nitrogen-containing compounds with acidic compounds, and combinations thereof. The nitrogen-containing compounds may include, for example, amine compounds, di-aza compounds, tri-aza compounds, polyamine compounds and combinations thereof. The acidic compounds may include phenol, organo-substituted phenols, carboxylic acids, sulfonic acids and combinations thereof. A suitable catalyst may be a salt of nitrogen-containing compounds. Salts of nitrogen-containing compounds may include, for example 1,8-diazabicyclo(5,4,0)-7-undecane. A suitable catalyst may include one or more of triphenyl phosphine (TPP), N-methylimidazole (NMI), and dibutyl tin dilaurate (DiBSn). The catalyst may be present in an amount in a range of from about 10 parts per million (ppm) to about 10 weight percent of the total composition.

As mentioned hereinabove, the cure catalyst may catalyze a curing reaction of the polymer precursor only at the second temperature, which is higher than the first temperature. In one embodiment, the polymer precursor may also be stable in the presence of a catalyst in a temperature range less than about the second temperature and for a specific period of time. In one embodiment, the polymer precursor may be stable in the presence of a catalyst at a temperature in a range of from about 20 degrees Celsius to about 75 degrees Celsius for a period of greater than about 10 minutes. In one embodiment, the polymer precursor may be stable in the presence of a catalyst at a temperature in a range of from about 75 degrees Celsius to about 150 degrees Celsius for a period of greater than about 10 minutes. In one embodiment, the polymer precursor may be stable in the presence of a catalyst at a temperature in a range of from about 150 degrees Celsius to about 200 degrees Celsius for a period of greater than about 10 minutes. In one embodiment, the polymer precursor may be stable in the presence of a catalyst at a temperature in a range of from about 200 degrees Celsius to about 300 degrees Celsius for a period of greater than about 10 minutes.

A hardener may be used. Suitable hardeners may include one or more of an amine hardener, a phenolic resin, a hydroxy aromatic compound, a carboxylic acid-anhydride, or a novolac hardener.

Suitable amine hardeners may include aromatic amines, aliphatic amines, or combinations thereof. Aromatic amines may include, for example, m-phenylene diamine, 4,4′-methylenedianiline, diaminodiphenylsulfone, diaminodiphenyl ether, toluene diamine, dianisidene, and blends of amines. Aliphatic amines may include, for example, ethyleneamines, cyclohexyldiamines, alkyl substituted diamines, methane diamine, isophorone diamine, and hydrogenated versions of the aromatic diamines. Combinations of amine hardeners may be used.

Suitable phenolic hardeners may include phenol-formaldehyde condensation products, commonly named novolac or cresol resins. These resins may be condensation products of different phenols with various molar ratios of formaldehyde. Such novolac resin hardeners may include those commercially available such as TAMANOL 758 or HRJ1583 oligomeric resins available from Arakawa Chemical Industries and Schenectady International, respectively.

Suitable hydroxy aromatic compounds may include one or more of hydroquinone, resorcinol, catechol, methyl hydroquinone, methyl resorcinol and methyl catechol. Suitable anhydride hardeners may include one or more of methyl hexahydrophthalic anhydride; methyl tetrahydrophthalic anhydride; 1,2-cyclohexanedicarboxylic anhydride; bicyclo(2.2.1) hept-5-ene-2,3-dicarboxylic anhydride; methyl bicyclo(2.2.1) hept-5-ene-2,3-dicarboxylic anhydride; phthalic anhydride; pyromellitic dianhydride; hexahydrophthalic anhydride; dodecenylsuccinic anhydride; dichloromaleic anhydride; chlorendic anhydride; tetrachlorophthalic anhydride; and the like. Combinations comprising at least two anhydride hardeners may be used. Anhydrides may hydrolyze to carboxylic acids useful for fluxing. In certain embodiments, a bifunctional siloxane anhydride may be used as a hardener, alone or in combination with at least one other hardener. Additionally, cure catalysts or organic compounds containing hydroxyl moiety may be added with the anhydride hardener.

An underfill composition may include additives. Suitable additives may be selected with reference to performance requirements for particular applications. For example, a fire retardant additive may be selected where fire retardancy may be desired, a flow modifier may be employed to affect rheology or thixotropy, a thermally conductive material may be added where thermal conductivity may be desired, and the like.

In one embodiment, a reactive organic diluent may be added to the underfill composition. A reactive organic diluent may include monofunctional compounds (having one reactive functional group) and may be added to decrease the viscosity of the composition. Suitable examples of reactive diluents may include 3-ethyl-3-hydroxymethyl oxetane; dodecylglycidyl; 4-vinyl-1-cyclohexane diepoxide; di(beta-(3,4-epoxycyclohexyl) ethyl) tetramethyldisiloxane; and the like. Reactive organic diluents may include monofunctional epoxies and/or compounds containing at least one epoxy functionality. Representative examples of such diluents may include alkyl derivatives of phenol glycidyl ethers such as 3-(2-nonylphenyloxy)-1,2-epoxypropane or 3-(4-nonylphenyloxy)-1,2-epoxypropane. Other diluents which may be used may include glycidyl ethers of phenol itself and substituted phenols such as 2-methylphenol, 4-methyl phenol, 3-methylphenol, 2-butylphenol, 4-butylphenol, 3-octylphenol, 4-octylphenol, 4-t-butylphenol, 4-phenylphenol and 4-(phenyl isopro-pylidene) phenol. An unreactive diluent may also be added to the composition to decrease the viscosity of the formulation. Examples of unreactive diluents include toluene, ethylacetate, butyl acetate, 1-methoxy propyl acetate, ethylene glycol, dimethyl ether, and combinations thereof.

In one embodiment, an adhesion promoter may be included in the composition. Suitable adhesion promoters may include one or more of trialkoxyorganosilanes (for example, γ-aminopropyltrimethoxysilane, 3-glycidoxy propyltrimethoxysilane, and bis(trimethoxysilylpropyl)fumarate). If present, the adhesion promoters may be added in an effective amount. An effective amount may be in a range of from about 0.01 weight percent to about 2 weight percent of the total final composition.

In one embodiment, flame retardants may be included in the composition. Suitable examples of flame retardants may include or more of phosphoramides, triphenyl phosphate (“TPP”), resorcinol diphosphate (“RDP”), bisphenol-a-disphosphate (“BPA-DP”), organic phosphine oxides, halogenated epoxy resin (tetrabromobisphenol A), metal oxide, metal hydroxides, and combinations thereof. When present, the flame retardant may be in a range of from about 0.5 weight percent to about 20 weight percent relative to the total weight.

In one embodiment, an underfill composition may include a filler to form a filled underfill composition. A filler may be included to control one or more of electrical property, thermal property, or mechanical property of the filled composition. In one embodiment, the filler selection is based on the desired electrical properties, thermal properties or both electrical and thermal properties of a layer formed from the composition. The filler may include a plurality of particles. The plurality of particles may be characterized by one or more of average particle size, particle size distribution, average particle surface area, particle shape, or particle cross-sectional geometry.

In one embodiment, an average particle size of the filler may be in a range of less than about 1 nanometer. In one embodiment, an average particle size of the filler may be in a range of from about 1 nanometer to about 10 nanometers, from about 10 nanometers to about 25 nanometers, from about 25 nanometers to about 50 nanometers, from about 50 nanometers to about 75 nanometers, or from about 75 nanometers to about 100 nanometers. In one embodiment, an average particle size of the filler may be in a range of from about 0.1 micrometers to about 0.5 micrometers, from about 0.5 micrometers to about 1 micrometer, from about 1 micrometer to about 5 micrometers, from about 5 micrometer to about 10 micrometers, from about 10 micrometers to about 25 micrometers, or from about 25 micrometer to about 50 micrometers. In one embodiment, an average particle size of the filler may be in a range of from about 50 micrometers to about 100 micrometers, from about 100 micrometers to about 200 micrometer, from about 200 micrometer to about 400 micrometers, from about 400 micrometer to about 600 micrometers, from about 600 micrometers to about 800 micrometers, or from about 800 micrometers to about 1000 micrometers. In one embodiment, an average particle size of the filler may be in a range of greater than about 1000 micrometers. In another embodiment, filler particles having two distinct size ranges (a bimodal distribution) may be included in the composition: the first range from about 1 nanometers to about 250 nanometers, and the second range from about 0.5 micrometer (or 500 nanometers) to about 10 micrometers (the filler particles in the second size range may be herein termed “micrometer-sized fillers”). A second range may be from about 0.5 micrometers to about 2 micrometers, or from about 2 micrometer to about 5 micrometers.

A filler particle may have a variety of shapes and cross-sectional geometries that may depend, in part, upon the process used to produce the particles. In one embodiment, a filler particle may have a shape which may be that of a sphere, a rods, a tube, a flake, a fiber, a plate, a whisker, or combinations of two or more thereof. The filler may include a plurality of particles having one or more of the aforementioned shapes. In one embodiment, a cross-sectional geometry of the particle may be one or more of circular, ellipsoidal, triangular, rectangular, or polygonal. In one embodiment, the filler may consist essentially of spherical particles. In one embodiment, the particles may include one or more active terminations sites on the surfaces (such as hydroxyl groups).

The fillers may be aggregates or agglomerates prior to incorporation into the composition or even after incorporation into the composition. An aggregate may include more than one filler particle in physical contact with one another, while agglomerates may include more than one aggregate in physical contact with one another. In some embodiments, the filler particles may not be strongly agglomerated and/or aggregated such that the particles may be relatively easily dispersed in the underfill composition. The filler particles may be subjected to mechanical or chemical processes to improve the dispersibility of the filler in the underfill composition. In one embodiment, the filler may be subjected to a mechanical process, for example, high shear mixing prior to dispersing in the underfill composition. In one embodiment, the filler particles may be chemically treated prior to dispersing in the underfill composition. Chemical treatment may include removing polar groups, for example hydroxyl groups, from one or more surfaces of the filler particles to reduce aggregate and/or agglomerate formation. Chemical treatment may also include functionalizing one or more surfaces of the filler particles with functional groups that may improve the compatibility between the fillers and the polymeric matrix, reduce aggregate and/or agglomerate formation, or both improve the compatibility between the fillers and the underfill composition and reduce aggregate and/or agglomerate formation.

In one embodiment, a filler may include a plurality of particles that may be electrically insulating. Suitable electrically insulating particles may include one or more of siliceous materials, metal hydrates, metal oxides, metal borides, or metal nitrides.

In one embodiment, a filler may include a plurality of particles that may be thermally conducting. Suitable thermally conducting particles may include one or more of siliceous materials (such as fumed silica, fused silica, or colloidal silica), carbonaceous materials, metal hydrates, metal oxides, metal borides, or metal nitrides.

In one embodiment, a filler may include silica and the silica may be colloidal silica. Colloidal silica may be a dispersion of submicron-sized silica (SiO₂) particles in an aqueous or other solvent medium. The colloidal silica may contain up to about 85 weight percent of silicon dioxide (SiO₂), and up to about 80 weight percent of silicon dioxide. The total content of silicon dioxide may be in the range from about 0.001 to about 1 weight percent, from about 1 weight percent to about 10 weight percent, from about 10 weight percent to about 20 weight percent, from about 20 weight percent to about 50 weight percent, or from about 50 weight percent to about 90 weight percent of the total composition weight.

In one embodiment, the colloidal silica may include compatibilized and passivated colloidal silica. Compatibilized and passivated silica may serve to reduce a coefficient of thermal expansion (CTE) of the composition, may function as spacers to control bond-line thickness, or both. In one embodiment, a plurality of particles (that is, silica filler) may be compatibilized and passivated by treatment with at least one organoalkoxysilane and at least one organosilazane. The two-component treatment may be done sequentially or may be done simultaneously. In sequential treatment, the organoalkoxysilane may be applied or reacted with at least a portion of active termination sites on the surface of the filler, and the organosilazane may be applied or reacted with at least a portion of the active termination sites that may remain after the reaction with the organoalkoxysilane.

After the reaction with the organoalkoxysilane, the otherwise phase incompatible filler may be relative more compatible or dispersible in an organic or non-polar liquid phase. An increase in the compatibility or dispersability of the filler in a matrix may be referred to herein as “compatibilized”. Organoalkoxysilanes used to functionalize the colloidal silica may be included within the formula (XXIV):

(R³⁰)ₖSi(OR³¹)₄₋ₖ (XXIV)

where R³⁰ may be independently at each occurrence an aliphatic radical, an aromatic radical, or a cycloaliphatic radical, optionally further functionalized with alkyl acrylate, alkyl methacrylate, an oxetane, or an epoxide group, R³¹ may be a hydrogen atom, an aliphatic radical, an aromatic radical, or a cycloaliphatic radical and “k” may be a whole number equal to 1 to 3 inclusive. The organoalkoxysilanes may include one or more of phenyl trimethoxy silane, 2-(3,4-epoxy cyclohexyl) ethyl trimethoxy silane, 3-glycidoxy propyl trimethoxy silane, or methacryloxy propyl trimethoxy silane.

Even though phase compatible with the pendant organic groups from the reaction with the organoalkoxysilane, residual active termination sites on the surface of the filler may initiate premature chemical reactions, may increase water absorption, may affect the transparency to certain wavelengths, or may have other undesirable side effects. In one embodiment, the phase compatible filler may be passivated by the capping of the active termination sites by a passivator or a passivating agent such as an organosilazane. Examples of organosilazanes may include one or more of hexamethyl disilazane (“HMDZ”), tetramethyl disilazane, divinyl tetramethyl disilazane, or diphenyl tetramethyl disilazane. The phase compatible, passivated filler may be admixed with a underfill composition, and may form a stable filled underfill composition. The organoalkoxysilane and the organosilazane are examples of a phase compatibilizer and a passivator, respectively.

Filled underfill compositions that include compatibilized and passivated particles may show relatively better room temperature stability than analogous formulations in which colloidal silica has not been passivated. In some cases, increasing room temperature stability of the underfill formulation may allow for higher loadings of curing agents, hardeners, and catalysts that might otherwise be undesirable due to shelf life constraints. By increasing those loadings, a higher degree of cure, a lower cure temperature, or more sharply defined cure temperature profiles may be achievable.

The amount of filler may be determined with reference to performance requirements for particular applications, the size of filler particles, or shape of the filler particles. In one embodiment, the filler may be present in an amount in a range of less than about 10 weight percent of the underfill composition. In one embodiment, the filler may be present in an amount in a range of from about 10 weight percent to about 15 weight percent of the underfill composition, from about 15 weight percent of the underfill composition to about 25 weight percent of the underfill composition, from about 25 weight percent of the underfill composition to about 30 weight percent of the underfill composition, or from about 30 weight percent of the underfill composition to about 40 weight percent of the underfill composition.

In one embodiment, the filler having colloidal and functionalized silica may further include micrometer-size fused silica. When present, the fused silica fillers may be added in an effective amount to provide further reduction in CTE, as spacers to control bond-line thickness, and the like. Defoaming agents, dyes, pigments, and the like may also be incorporated into composition. The amount of such additives may be determined by the end-use application.

A melt viscosity of the filled underfill composition may depend on one or more of the filler loading, filler particle shape, filler particle size, molecular weight of the components, or percentage conversion. In one embodiment, the filled underfill composition may have flow properties (for example viscosity) at a particular temperature such that the filled underfill composition may flow between two surfaces, for example between a chip and a substrate. A filled underfill composition prepared according to one embodiment, of the invention may be solvent free. A solvent free filled underfill composition in accordance with one embodiment, of the invention may have sufficiently low viscosity such that the composition may flow between a chip and a substrate.

In one embodiment, a filled underfill composition may have a room temperature viscosity in a range of less than about 20000 centipoise when the filler is present in an amount in a range of greater than about 10 weight percent of the filled underfill composition. In one embodiment, a filled underfill composition may have a room temperature viscosity in a range of from about 100 centipoise to about 1000 centipoise, from about 1000 centipoise to about 2000 centipoise, from about 2000 centipoise to about 5000 centipoise, from about 5000 centipoise to about 10000 centipoise, from about 10000 centipoise to about 15000 centipoise, or from about 15000 centipoise to about 20000 centipoise, when the filler is present in an amount in a range of greater than about 10 weight percent of the filled underfill composition.

Stability of the filled composition may also depend on one or more of filler loading, temperature, ambient conditions, or percentage conversion. In one embodiment, the filled underfill composition may be stable at a temperature in a range of greater than about 20 degrees Celsius for a period of greater than about 1 day. In one embodiment, the filled composition may be stable at a temperature in a range of from about 20 degrees Celsius to about 50 degrees Celsius, from about 50 degrees Celsius to about 75 degrees Celsius, from about 75 degrees Celsius to about 100 degrees Celsius, from about 100 degrees Celsius to about 150 degrees Celsius, or from about 150 degrees Celsius to about 175 degrees Celsius, and for a period of greater than about 1 day. In one embodiment, the filled underfill composition may be stable at a temperature in a range of greater than about 175 degrees Celsius for a period of greater than about 1 day. In one embodiment, the filled underfill composition may be stable at a temperature in a range of greater than about 175 degrees Celsius for a period of greater than about 10 days. In one embodiment, the filled underfill composition may be stable at a temperature in a range of greater than about 175 degrees Celsius for a period of greater than about 30 days. In one embodiment, a filled underfill composition may be stored without refrigeration for a period of greater than about 1 day.

A filled underfill composition in addition to being used as underfill materials may also be used as thermal interface materials in electronic packaging articles. Suitability of the filled underfill composition for a particular application may depend on one or more of the electrical, thermal, mechanical or flow properties of the filled underfill composition. Thus, by way of example, an underfill material may require a filled composition that is electrically insulating and has the required thermal properties, such as coefficient of thermal expansion, thermal fatigue, and the like.

In one embodiment, an underfill material may include the filled composition. Underfill materials may be dispensable and may have utility in devices such as solid-state devices and/or electronic devices such as computers or semiconductors, or a device where underfill, overmold, or combinations thereof may be needed. The underfill material may be used as an adhesive, for example, to reinforce physical, mechanical, and electrical properties of electrical interconnects that connect a chip and a substrate. In certain embodiments, the underfill material may have self-fluxing capabilities.

In one embodiment, an underfill material may be cured at the first temperature to form a B-stage layer. In one embodiment, an underfill material may be cured to form a cured underfill layer. The cured underfill layer may be formed directly by heating the underfill layer to a second temperature or by sequential heating to the first temperature (to form the B-staged layer) and then heating to the second temperature. During sequential heating, B-staged layer may be cooled to room temperature, exposed to other processing steps, and then subsequently heated to form the cured underfill layer. In one embodiment, the underfill material includes an alcohol and an anhydride that cures at a temperature in a range of less than about 150 degrees Celsius and an oxetane-functionalized polymer precursor that cures at a temperature in a range of from about 150 degrees Celsius to about 300 degrees Celsius. Curing of the alcohol and the anhydride may result in B-staged layer and subsequent curing of the oxetane-functionalized precursor may result in a cured underfill layer.

In one embodiment, a percent conversion of the alcohol and the anhydride and the oxetane-functionalized precursor may be greater than about 50 percent in the cured underfill layer. In one embodiment, a percent conversion of alcohol and the anhydride and the oxetane-functionalized precursor may be greater than about 60 percent in the cured underfill layer. In one embodiment, a percent conversion of alcohol and the anhydride and the oxetane-functionalized precursor may be greater than about 75 percent in the cured underfill layer. In one embodiment, a percent conversion of alcohol and the anhydride and the oxetane-functionalized precursor may be greater than about 90 percent in the cured underfill layer. In one embodiment, a percent conversion of alcohol and the anhydride may be greater than about 75 percent and a percent conversion of the oxetane-functionalized precursor may be greater than about 50 percent in the cured underfill layer.

In one embodiment, a cured underfill layer may secure a chip to the substrate. In one embodiment, a cured underfill layer may functionally support one or more electrical connects between a chip and substrate. The cured underfill layer may provide functional support by one or more of reinforcing the interconnect, by absorbing stress, by reducing thermal fatigue, or by being electrically insulating. Thermal fatigue may develop between a chip and a substrate due to a mismatch of coefficient of thermal expansion between a chip and a substrate. In one embodiment, the cured underfill layer may reduce the thermal fatigue developed by having a coefficient of thermal expansion that reduces the mismatch.

Because of factors, such as filler amount, the coefficient of thermal expansion of cured underfill layer, may be selected to be less than about 50 ppm/degree Celsius, less than about 40 ppm/degree Celsius, or less than about 30 ppm/degree Celsius. In one embodiment, the coefficient of thermal expansion may be in a range of from about 10 ppm/degree Celsius to about 20 ppm/degree Celsius, from about 20 ppm/degree Celsius to about 30 ppm/degree Celsius, from about 30 ppm/degree Celsius to about 40 ppm/degree Celsius, or greater than about 40 ppm/degree Celsius.

Mechanical properties (such as modulus) and thermal properties of the cured underfill layer may also depend on the glass temperature of the composition. In one embodiment, a glass transition temperature of the cured underfill layer may be greater than about 150 degrees Celsius, greater than about 200 degrees Celsius, greater than about 250 degrees Celsius, greater than about 300 degrees Celsius, or greater than about 350 degrees Celsius. In one embodiment, a modulus of the cured underfill layer may be in a range of greater than about 2000 MegaPascals, greater than about 3000 MegaPascals, greater than about 5000 MegaPascals, greater than about 7000 MegaPascals, or greater than about 10000 MegaPascals.

Electrically insulating properties of the underfill material may depend on factors, such as, filler type and concentration. In one embodiment, a cured underfill layer may have an electrical resistivity in a range of greater than about 10⁻³ Ohm. centimeter, greater than about 10⁻⁴ Ohm. centimeter, 10⁻⁵ Ohm. centimeter, or 10⁻⁶ Ohm. centimeter. In addition to the being electrically insulating, a cured underfill may also be thermally conductive, if required, to function as a thermal interface material. As a thermal interface material, the underfill layer may facilitate heat transfer from the chip to the substrate. The substrate in turn may be coupled to a heat-dissipating unit, such a heat sink, heat radiator, or a heat spreader. Similar to the electrical properties, thermal conductivity (or resistivity) values of the cured underfill layer may also depend on factors, such as, filler type and concentration. In one embodiment, a cured underfill layer may have a thermal conductivity in a range of greater than about 1 W/mK at 100 degrees Celsius, greater than about 2 W/mK at 100 degrees Celsius, greater than about 5 W/mK at 100 degrees Celsius, greater than about 10 W/mK at 100 degrees Celsius, or greater than about 20 W/mK at 100 degrees Celsius.

A cured underfill layer may also be required to be stable at the operating conditions. In one embodiment, a cured underfill layer may be stable at a humidity value greater than about 10 percent and at a temperature greater than about 20 degrees Celsius, at a humidity value greater than about 50 percent and at a temperature greater than about 20 degrees Celsius, at a humidity value greater than about 80 percent and at a temperature greater than about 20 degrees Celsius, at a humidity value greater than about 10 percent and at a temperature greater than about 40 degrees Celsius, at a humidity value greater than about 10 percent and at a temperature greater than about 80 degrees Celsius, or at a humidity value greater than about 80 percent and at a temperature greater than about 80 degrees Celsius.

In one embodiment, the cured underfill layer may have the desired transparency required for wafer level underfills. Suitable transparency is defined as being capable of transmitting sufficient light so as to not obscure guide marks used for wafer dicing. In one embodiment, the transparency of the cured underfill layer is in a range of greater than about 50 percent visible light transmission, in a range of from about 50 percent to about 75 percent, from about 75 percent to about 85 percent, from about 85 percent to about 90 percent, or greater than about 90 percent visible light transmission. In one embodiment, the transparency may be measured with reference to light in a wavelength outside of the visible spectrum. In such an embodiment, the light transmission may be sufficient to allow a detector or sensor to discern guide marks for wafer dicing.

In one embodiment, the underfill material (prior to or after curing) may be free of solvent or other volatiles. Volatiles may result in formation of voids during one or more processing steps, for example curing of the alcohol and the anhydride to form a B-stage layer. Voids may result in undesirable defect formation. In one embodiment, the curing reaction of the alcohol and the anhydride produces an insufficient amount of gas to form visually detectable voids prior to, during, or after curing.

As noted, the cured underfill layer secures the chip to the substrate. Effectiveness of the cured underfill layer in securing the chip to the substrate may depend on factors such as interfacial adhesion between the underfill layer and the chip or the substrate or shrinkage (if any) after curing of the underfill layer. Interfacial properties between the underfill material and the chip or the substrate may be improved by choosing an oxetane-functionalized polymer precursor with the desired interfacial properties, for example adhesive properties. In one embodiment, an oxetane-functionalized polymer precursor may form a continuous interfacial contact with a substrate prior to curing. In one embodiment, an oxetane-functionalized polymer precursor may form a continuous interfacial contact with a chip prior to curing. In one embodiment, a cured underfill layer may form a continuous interfacial contact with a substrate and a chip after curing.

An article may include an underfill material disposed between a chip and a substrate. An article may include solid-state devices and or electrical devices such as computers or semiconductors, or a device where underfill, over mold, or combinations thereof may be needed. The underfill material may be cured to formed a cured underfill layer, as described hereinabove. In one embodiment, the cured underfill layer may secure the chip to the substrate in the device.

In one embodiment, the article may further include electrical interconnects and the cured underfill layer may be used to functionally support the electrical connects between the chip and the substrate from thermal fatigue. In one embodiment, the electrical reconnects may include solder bumps, and the cured underfill layer may function as an adhesive, for example, to reinforce physical, mechanical, and electrical properties of the solder bumps. Electrical interconnects may include lead or may be free of lead. Lead-free interconnects may include electrically conductive particles or electrically conducting particles dispersed in polymeric matrix. In one embodiment, a polymer precursor may cure around the soldering (lead-based) or crosslinking (lead-free) temperature of the interconnects. In one embodiment, a polymer precursor may cure at a temperature higher than the soldering (lead-based) or crosslinking (lead-free) temperature of the interconnects.

A method for making an underfill composition (filled or unfilled), in accordance with one embodiment, of the invention is provided. The method includes making an underfill composition having an oxetane functionalized polymer precursor. An oxetane functionalized precursor may be obtained commercially or synthesized as described hereinabove. The underfill composition may also be contacted with a filler to form a filled composition. The step of contacting may include mixing/blending in solid-form, melt form, or by solution mixing.

Solid-or melt-blending of the filler and the underfill composition may involve the use of one or more of shear force, extensional force, compressive force, ultrasonic energy, electromagnetic energy, or thermal energy. Blending may be conducted in a processing equipment wherein the aforementioned forces may be exerted by one or more of single screw, multiple screws, intermeshing co-rotating or counter rotating screws, non-intermeshing co-rotating or counter rotating screws, reciprocating screws, screws with pins, barrels with pins, rolls, rams, or helical rotors. The materials may by hand mixed but also may be mixed by mixing equipment such as dough mixers, chain can mixers, planetary mixers, twin screw extruder, two or three roll mill, Buss kneader, Henschel, helicones, Ross mixer, Banbury, roll mills, molding machines such as injection molding machines, vacuum forming machines, blow molding machine, or the like. Blending may be performed in batch, continuous, or semi-continuous mode. With a batch mode reaction, for instance, all of the reactant components may be combined and reacted until most of the reactants may be consumed. In order to proceed, the reaction has to be stopped and additional reactant added. With continuous conditions, the reaction does not have to be stopped in order to add more reactants. Solution blending may also use additional energy such as shear, compression, ultrasonic vibration, or the like to promote homogenization of the filler in the underfill composition. A filled or an unfilled composition may also be contacted with a cure catalyst prior to blending or after blending.

In one embodiment, a filled composition may be prepared by solution blending of an alcohol (if present), an anhydride (if present), an oxetane-functionalized polymer precursor, and the filler. In one embodiment, the oxetane-functionalized polymer precursor may be suspended in a fluid and then introduced into an ultrasonic sonicator along with the filler to form a mixture. The mixture may be solution blended by sonication for a time period effective to disperse the filler particles within the polymer precursor. In one embodiment, the fluid may swell the polymer precursor during the process of sonication. Swelling of the polymer precursor may improve the ability of the filler to impregnate the polymer precursor during the solution blending process and consequently improve dispersion.

Solvents may be used in the solution blending of the underfill composition. A solvent may be used as a viscosity modifier, or to facilitate the dispersion and/or suspension of the filler composition. Liquid aprotic polar solvents such as one or more of propylene carbonate, ethylene carbonate, butyrolactone, acetonitrile, benzonitrile, nitromethane, nitrobenzene, sulfolane, dimethylformamide, N-methylpyrrolidone, or the like, may be used. Polar protic solvents such as one or more of water, methanol, acetonitrile, nitromethane, ethanol, propanol, isopropanol, butanol, or the like, may be used. Other non-polar solvents such as one or more of benzene, toluene, methylene chloride, carbon tetrachloride, hexane, diethyl ether, tetrahydrofuran, or the like, may also be used. Co-solvents comprising at least one aprotic polar solvent and at least one non-polar solvent may also be used. The solvent may be evaporated before, during and/or after the blending of the composition. After blending, the solvent may be removed by one or both of heating or application of vacuum. Removal of the solvent from the composition may be measured and quantified by an analytical technique such as, infra-red spectroscopy, nuclear magnetic resonance spectroscopy, thermo gravimetric analysis, differential scanning calorimetric analysis, and the like.

In one embodiment, the filler may include colloidal silica and the colloidal silica may be compatibilized and passivated prior to blending (solid, melt or solution blending). The compatibilization of colloidal silica may be performed by adding the compatibilization agent to an aqueous dispersion of colloidal silica to which an aliphatic hydroxyl has been added. The resulting composition including the compatibilized silica particles and the compatibilization agent in the aliphatic hydroxyl may be defined herein as a pre-dispersion. The aliphatic hydroxyl may be selected from isopropanol, t-butanol, 2-butanol, and combinations thereof. The amount of aliphatic hydroxyl may be in a range of from about 1 fold to about 10 fold by weight of the amount of silicon dioxide present in the aqueous colloidal silica pre-dispersion.

The resulting organo-compatibilized silica particles may be treated with an acid or base to neutralize the pH. An acid or base as well as other catalyst promoting condensation of silanol and alkoxysilane groups may be used to aid the compatibilization process. Such catalysts may include organo-titanate and organo-tin compounds such as tetrabutyl titanate, titanium isopropoxy bis(acetylacetonate), dibutyltin dilaurate, or combinations thereof. In some cases, stabilizers such as 4-hydroxy-2,2,6,6-tetramethylpiperidinyloxy (i.e. 4-hydroxy. TEMPO) may be added to the pre-dispersion. The resulting pre-dispersion may be heated in a range of from about 50 degrees Celsius to about 100 degrees Celsius for a period in a range of from about 1 hour to about 12 hours. A curing time range of from about 1 hour to about 5 hours may be adequate.

The cooled transparent pre-dispersion may be further treated with a passivating agent as disclosed herein to form a final dispersion. Optionally, curable polymer precursors and aliphatic solvent may be added during this process step. Suitable additional solvent may be selected from isopropanol, 1-methoxy-2-propanol, 1-methoxy-2-propyl acetate, toluene, and combinations of two or more thereof. The final dispersion of the compatibilized and passivated particles may be treated with acid or base or with ion exchange resins to remove acidic or basic impurities.

The final dispersion of compatibilized and passivated particles (having been compatibilized and passivated as disclosed herein) may be hand-mixed, or may be mixed by one or more of dough mixers, chain mixers, or planetary mixers depending on application influenced factors. Such factors may include viscosity, reactivity, particle size, batch size, and process parameters—such as temperature. The blending of the dispersion components may be performed in batch, continuous, or semi-continuous mode.

The final dispersion of the compatibilized and passivated particles may be concentrated under a vacuum in a range of from about 0.5 Torr to about 250 Torr and at a temperature in a range of from about 20 degrees Celsius to about 140 degrees Celsius to remove any low boiling components such as solvent, residual water, and combinations thereof to give a transparent dispersion of compatibilized and passivated silica particles which may optionally contain curable monomer, here referred to as a final concentrated dispersion. Removal of low boiling components may be defined herein as removal of low boiling components to give a concentrated silica dispersion containing from about 15 weight percent to about 80 weight percent silica.

In some instances, the pre-dispersion or the final dispersion of the compatibilized and passivated silica particles may be further reacted with a compatibilization agent and/or a passivating agent. Low boiling components may be at least partially removed. Subsequently, a second capping agent or passivating agent that may react with any remaining or residual hydroxyl functionality (left after the first pass through the compatibilizing and passivating process) of the compatibilized and passivated particles may be added in an amount in a range of from about 0.05 times to about 10 times the amount by weight of silicon dioxide present in the pre-dispersion or final dispersion. Partial removal of low boiling components may remove at least about 10 weight percent of the total amount of low boiling point components, an amount of low boiling point components in a range of from about 10 weight percent to about 50 weight percent, or greater than about 50 weight percent of the total amount of low boiling point components. For at least the second pass through the compatibilizing and passivating process, an effective amount of capping agent may react with surface functional groups of the compatibilized and passivated particles. In one embodiment, the compatibilized and passivated particles may have, after final processing, at least 10 weight percent, at least 20 weight percent, or at least 35 weight percent fewer free hydroxyl groups present compared to a corresponding group of unpassivated particles.

In one embodiment, a filled or unfilled underfill composition prepared according to one embodiment, of the invention may be heated to a first temperature to cure the alcohol and the anhydride (if present). Curing of the alcohol and the anhydride may result in a B-stage-composition that is tack-free, a solid, or both tack-free and solid. The B-staged composition may be later heated to a second temperature, which is higher than the first temperature, to cure the oxetane-functionalized polymer precursor.

In one embodiment, a filled or unfilled composition (underfill) may be disposed on the surface of a chip, on the surface of a wafer, on the surface of a substrate, or between a chip and substrate, prior to B-staging. The method of disposing the underfill composition may be referred to as underfilling. Underfilling may include capillary underfilling, no-flow underfilling, transfer mold underfilling, wafer level underfilling and the like.

Capillary underfilling includes dispensing the underfill material in a fillet or bead extending along two or more edges of the chip and allowing the underfill material to flow by capillary action under the chip to fill all the gaps between the chip and the substrate. The underfill may be dispensed using a needle in a dot pattern in the center of the component footprint area. Other suitable dispensing methods may include a jetting method—dots on the fly or line mode—and a DJ-9000 DispenseJet, which is commercially available from Asymtek (Carlsbad, Calif.). The process of transfer molded underfilling includes placing a chip and substrate within a mold cavity and pressing the underfill material into the mold cavity. Pressing the underfill material fills the air spaces between the chip and substrate with the underfill material.

The process of no-flow underfilling includes first dispensing the underfill material on the substrate or semiconductor device and second placing a flip chip on the top of the underfill and third performing the electrical connect (solder bump) reflow to form electrical connects (solder joints) and cure underfill simultaneously. The wafer level underfilling process includes dispensing underfill materials onto the wafer before dicing into individual chips that may be subsequently mounted in the final structure via flip-chip type operations.

The flip-chip die (or chip) may be placed on the top of the substrate using an automatic pick and place machine. The placement force as well as the placement head dwell time may be controlled to optimize cycle time and yield of the process. The construction may be heated to melt or reflow the electrical interconnects (e.g., solders), form electrical interconnects and finally cure the underfill. The heating operation may be performed on the conveyor in the reflow oven. The cure kinetics of the underfill (that is, oxetane-functionalized polymer precursor) may be tuned to fit a temperature profile of the reflow cycle. The no-flow or wafer-level underfill may allow the interconnect (solder joint) formation before the underfill reaches a gel point and may form a solid underfill layer at the end of the heat cycle.

No-flow or wafer-level underfills may be cured using two significantly different reflow profiles. The first profile may be referred to as the “plateau” profile, which includes a soak zone below the melting point of the solder. The second profile, referred to as the “volcano” profile, raises the temperature at a constant heating rate until the maximum temperature may be reached. The maximum temperature during the reflow depends on the solder composition and may be about 10 degrees Celsius to about 40 degrees Celsius higher than the melting point of the solder balls or reflow temperature of the solder balls (for lead-free). The heating cycle may be between about 3 minutes to about 5 minutes, or from about 5 minutes to about 10 minutes. In one embodiment, the cured underfill layer may be post-cured at a temperature in a range of from about 150 degrees Celsius to about 180 degrees Celsius, from about 180 degrees Celsius to about 200 degrees Celsius, from about 200 degrees Celsius to about 250 degrees Celsius, or from about 250 degrees Celsius to about 300 degrees Celsius, over a period of time in a range of from about 1 hour to about 4 hours.

In one embodiment, a filled or an unfilled underfill composition may be disposed on a substrate to form a no-flow underfill. Alcohol and anhydride (if present) are cured to a first temperature to form a B-staged no-flow underfill. A flip chip is placed on the top of the B-staged underfill to form an electrical assembly. This is followed by heating the electrical assembly to reflow the electrical interconnects (solders) to form electrical interconnects (solder joints). During the reflow flow process, the polymer precursor is cured simultaneously to form a cured underfill layer. The cure temperature of the polymer precursor (second curing temperature) and the reflow temperature may be tuned such that simultaneous curing and reflow happens.

In one embodiment, a filled or an unfilled composition may be disposed on a wafer to form a wafer-level underfill. Alcohol and anhydride (if present) are cured to a first temperature to form a B-staged wafer level underfill. The wafer is diced into individual chips and individual chips are placed on top of the substrate to form an electrical assembly. This is followed by heating the electrical assembly to reflow the electrical interconnects (solders) and form electrical interconnects (solder joints). During the reflow flow process, the polymer precursor is cured simultaneously to form a cured underfill layer. The cure temperature of the polymer precursor (second curing temperature) and the reflow temperature may be tuned such that simultaneous curing and reflow happens. In one embodiment, an underfill material may be particularly useful as a wafer-level underfill.

By using one of the aforementioned underfilling methods, a chip may be packaged to form an electronic assembly. Chips that may be packaged using the underfill composition may include semiconductor chips and LED chips. A suitable chip may include a semiconductor material, such as silicon, gallium, germanium or indium, or combinations of two or more thereof. Electronic assembly may be used in electronic devices, integrated circuits, semiconductor devices, and the like. Integrated circuits and other electronic devices employing the underfill materials may be used in a wide variety of applications, including personal computers, control systems, telephone networks, and a host of other consumer and industrial products.

### EXAMPLES

The following examples are intended only to illustrate methods and embodiments in accordance with the invention, and as such should not be construed as imposing limitations upon the claims. Unless specified otherwise, all ingredients may be commercially available from such common chemical suppliers as Alpha Aesar, Inc. (Ward Hill, Mass.), Sigma Aldrich, Spectrum Chemical Mfg. Corp. (Gardena, Calif.), and the like.

### Example 1

A monofunctional alcohol, 3-ethyl-3-hydroxymethyl-oxetane (available under the tradename of UVR6000 from Dow Chemicals) is mixed with a methylhexahydrophthalic anhydride (MHHPA). Mixing was carried out room temperature using a magnetic stirrer and in the absence of solvent. The resulting mixture was coated on a glass slide prior to heating and analysis.

Two different samples are prepared by varying the ratio of hydroxyl groups to the anhydride groups. Sample 1 is prepared using a 1:1 molar ratio of UVR6000 to MHHPA. Sample 2 is prepared using a 1:3 molar ratio of UVR6000 to MHHPA. Samples 1 and 2 are heated to a temperature of 100 degrees Celsius for a period of 1 hour, and the properties of the resulting composition were examined visually for viscosity/tackiness. Table 1 shows the sample compositions and the final properties of the two samples after heating.

TABLE 1
B-stage properties of samples

| | | | Final state |
|---|---|---|---|
| | Ratio of hydroxyl | Initial state of the | of the composition |
| Sample | to anhydride | composition | after heating |
| 1 | 1:1 | Liquid | Highly viscous liquid |
| 2 | 1:3 | Liquid | Medium viscosity liquid |

### Example 2

3-bromomethyl-3-methyloxetane (82.5 g, 0.5 mol) is added to a round bottom flask equipped with mechanical stirring and a condenser. Methylhydroquinone (31.04 g, 0.25 mol) is added to the flask followed by 25 g of water. Tetrabutylammonium bromide (8.0 g, 0.025 mol) is slowly added to the resulting mixture. Subsequently the mixture is heated to 75° C. and potassium hydroxide (35.5 g in 50 g of water) is added dropwise. The resulting mixture is heated at 80° C. for 18 hours. The mixture is cooled to room temperature and filtered followed by diluting with water and extraction with methylene chloride. Evaporation of methylene chloride produces 42.1 g of crude product that is subsequently recrystallized from hot hexanes to yield 31.7 g of a light yellow solid, methyl hydroquinone oxetane (MeHQOx).

### Example 3

A master batch is prepared without catalyst according to the following procedure. In a round bottom flask compatibilized and passivated silica, MeHQOx (prepared in Example 2), MHHPA and glycerol are added and mixed to yield a homogeneous solution. Solvent is then removed via rotovaporation, which includes a 30 minutes heating at 90° C. and full vacuum after the point where visual solvent removal has ceased. Table 2 is an illustrative formulation that may be used to prepare a master batch.

TABLE 2
Masterbatch formulation

| | | |
|---|---|---|
| Components | Weight (g) | Solid % |

| | | | |
|---|---|---|---|
| Compatibilized and passivated silica | 11.36 | | 26.4 |
| in methoxypropanol | | | |
| MeHQOx | 5.09 | g | |
| MHHPA | 5.84 | g | |
| Glycerol | 1.07 | g | |
| Final composition | 15.00 | | 20.0 |

### Example 4

A catalyst (tetraphenylphosphonium Bromide, TPPB) is blended into the masterbatch prepared in Example 3. Table 3 shows the formulation used to prepare the final composition. The samples 3 and 4 are then degassed and transferred to syringes and their B-stage and curing properties are measured.

TABLE 3
Formulations with catalyst

Sample

| Final Material composition | 3 | 4 |
|---|---|---|
| Master batch (g) | 4 | 4 |
| TPPB (g) | 0.17 | 0.257 |
| weight percent catalyst | 4.3% | 6.4% |
| weight percent filler | 20.0% | 20.0% |

### Example 5

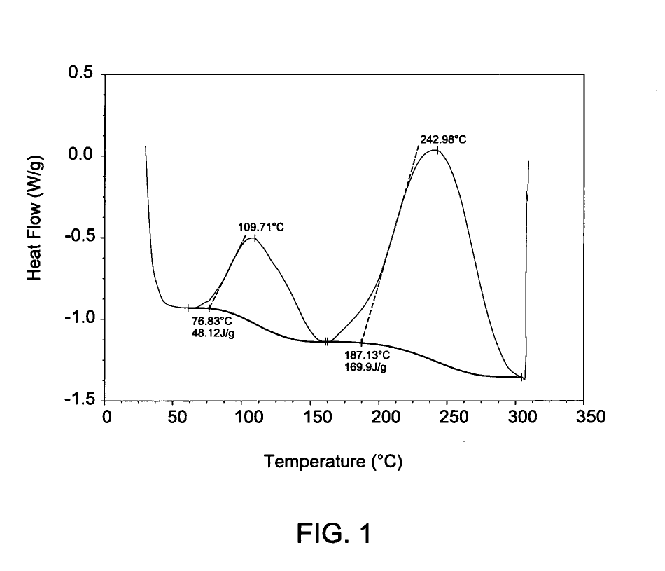

Liquid samples 3 and 4 are tested for glass transition temperature, T_{g}, cure kinetics, and viscosity. T_{g} and cure kinetics are determined using differential scanning calorimetry (DSC) by heating at a heating rate of 30 C/min. Table 4 shows the properties of the two compositions. DSC cure shows two distinct exotherms centered at 110 degrees Celsius and 240 degrees Celsius respectively as illustrated in FIG. 1. The initial exotherm (DSC cure 1) may be attributed to the B-stage reaction (alcoholysis of anhydride) and the second exotherm (DSC cure 2) may be representative of bulk resin cure (cure of the oxetane resin).

TABLE 4
Viscosity, T_{g} and cure characteristics of liquid samples

Sample

| Properties | 3 | 4 |
|---|---|---|
| Room temperature viscosity (cPs) | 2610 | 2680 |
| T_{g} (DSC, ° C.) | 71 | 74 |
| DSC cure 1 onset (° C.) | 77 | 74 |
| DSC cure 1 peak (° C.) | 110 | 107 |
| Heat of reaction 1(J/g) | 48 | 43 |
| DSC cure 2 onset (° C.) | 187 | 181 |
| DSC cure peak (° C.) | 243 | 236 |
| Heat of reaction 1(J/g) | 171 | 162 |

### Example 6

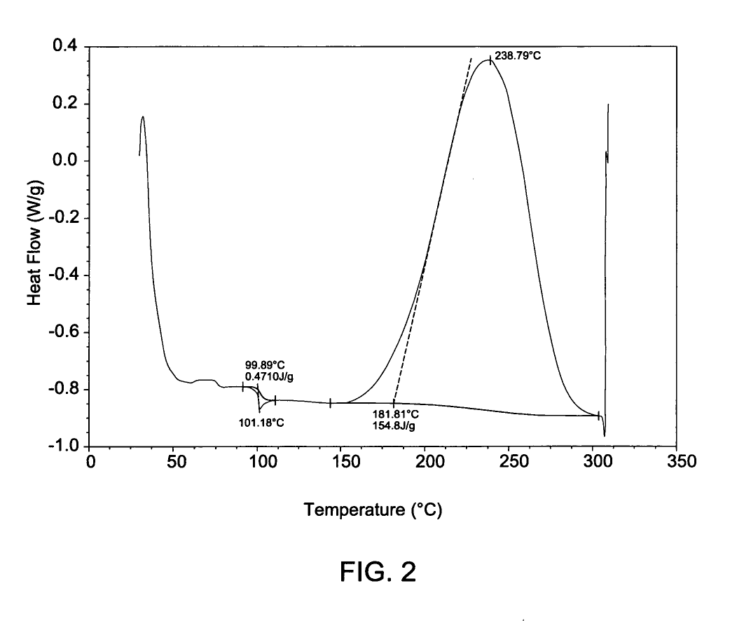

Liquid samples 3 and 4 are first B-staged by heating the samples for 2 hours at 100° C. yielding a hard non-tack film (Samples 5 and 6). B-stage hardness of the films is determined visually. The B-staged samples are then tested for curing characteristics using DSC by heating at a heating rate of 30 C/min. Table 5 shows the properties of the two B-staged compositions. When subjected to DSC analysis only the cure peak centered at 240° C. remains, as illustrated in FIG. 2. In addition, the heat of reaction value for this peak is equal to that measured for samples cured from the liquid state (Example 5), possibly suggesting no bulk resin cure takes place during B-staging.

TABLE 5
Cure characteristics of B-staged samples

Sample

| Properties | 5 | 6 |
|---|---|---|
| B-stage properties after heating at | solid | solid |
| 100° C. for 2 hours | | |
| DSC cure 1 onset (° C.) | — | — |
| DSC cure 1 peak (° C.) | — | — |
| Heat of reaction 1(J/g) | — | — |
| DSC cure 2 onset (° C.) | 182 | 176 |
| DSC cure peak (° C.) | 239 | 229 |
| Heat of reaction 1(J/g) | 155 | 151 |

### Example 7

A 1,2,3,4,5,6,7,8-butanol-functionalized silsesquioxane is reacted with 3-bromomethyl-3-ethyl oxetane to form oxetane-functionalized silsesquioxane having a structure of formula (XIV) (Sample 7). A master batch is prepared without catalyst according to the following procedure. In a round bottom flask compatibilized and passivated silica, Sample 7, MHHPA and glycerol are added and mixed to yield a homogeneous solution. Solvent is then removed via rotovaporation, which includes a 30 minutes heating at 90° C. and full vacuum after the point where visual solvent removal has ceased. A catalyst (tetraphenylphosphonium Bromide, TPPB) is blended into the masterbatch to form Sample 8. Sample 8 is degassed and transferred to a syringe and its B-stage and curing properties are measured by DSC. A DSC thermogram of Sample 8 may show a first peak due to the B-stage reaction of MHHPA and glycerol with a peak temperature in a range of lower than about 150 degrees Celsius. A DSC thermogram of Sample 8 may also show a second peak due to curing of the oxetane-functionalized silsesquioxane with a peak temperature in a range of greater than about 150 degrees Celsius.

Reference is made to substances, components, or ingredients in existence at the time just before first contacted, formed in situ, blended, or mixed with one or more other substances, components, or ingredients in accordance with the present disclosure. A substance, component or ingredient identified as a reaction product, resulting mixture, or the like may gain an identity, property, or character through a chemical reaction or transformation during the course of contacting, in situ formation, blending, or mixing operation if conducted in accordance with this disclosure with the application of common sense and the ordinary skill of one in the relevant art (e.g., chemist). The transformation of chemical reactants or starting materials to chemical products or final materials is a continually evolving process, independent of the speed at which it occurs. Accordingly, as such a transformative process is in progress there may be a mix of starting and final materials, as well as intermediate species that may be, depending on their kinetic lifetime, easy or difficult to detect with current analytical techniques known to those of ordinary skill in the art.

Reactants and components referred to by chemical name or formula in the specification or claims hereof, whether referred to in the singular or plural, may be identified as they exist prior to coming into contact with another substance referred to by chemical name or chemical type (e.g., another reactant or a solvent). Preliminary and/or transitional chemical changes, transformations, or reactions, if any, that take place in the resulting mixture, solution, or reaction medium may be identified as intermediate species, master batches, and the like, and may have utility distinct from the utility of the reaction product or final material. Other subsequent changes, transformations, or reactions may result from bringing the specified reactants and/or components together under the conditions called for pursuant to this disclosure. In these other subsequent changes, transformations, or reactions the reactants, ingredients, or the components to be brought together may identify or indicate the reaction product or final material.

The foregoing examples are illustrative of some features of the invention. The appended claims are intended to claim the invention as broadly as has been conceived and the examples herein presented are illustrative of selected embodiments from a manifold of all possible embodiments. Accordingly, it is Applicants' intention that the appended claims not limit to the illustrated features of the invention by the choice of examples utilized. As used in the claims, the word “comprises” and its grammatical variants logically also subtend and include phrases of varying and differing extent such as for example, but not limited thereto, “consisting essentially of” and “consisting of.” Where necessary, ranges have been supplied, and those ranges are inclusive of all sub-ranges there between. It is to be expected that variations in these ranges will suggest themselves to a practitioner having ordinary skill in the art and, where not already dedicated to the public, the appended claims should cover those variations. Advances in science and technology may make equivalents and substitutions possible that are not now contemplated by reason of the imprecision of language; these variations should be covered by the appended claims.

1. An underfill composition, comprising:
a polymer precursor comprising 4 or more pendant oxetane functional groups;
and the polymer precursor comprises greater than about 20 weight percent of the underfill composition.

2. The underfill composition as defined in claim 1, wherein the polymer precursor includes 6 or more pendant oxetane functional groups.

3. The underfill composition as defined in claim 1, wherein the polymer precursor comprises monomeric species, oligomeric species, mixtures of monomeric species, mixtures of oligomeric species, or mixtures of two or more of the foregoing.

4. The underfill composition as defined in claim 3, wherein the polymer precursor is the reaction product of one or more material selected from the group consisting of 3-bromomethyl-3-hydroxymethyl oxetane; 3,3-bis-(ethoxymethyl) oxetane; 3,3-bis-(chloromethyl) oxetane; 3,3-bis-(methoxymethyl) oxetane; 3,3-bis-(fluoromethyl) oxetane; 3-hydroxymethyl-3-methyl oxetane; 3,3-bis-(acetoxymethyl) oxetane; 3,3-bis-(hydroxy methyl) oxetane; 3-octoxy methyl-3-methyl oxetane; 3-chloromethyl-3-methyl oxetane; 3-azidomethyl-3-methyl oxetane; 3,3-bis-(iodomethyl) oxetane; 3-iodomethyl-3-methyl oxetane; 3-propyno methyl-3-methyl oxetane; 3-nitrato methyl-3-methyl oxetane; 3-difluoro amino methyl-3-methyl oxetane; 3,3-bis-(difluoro amino methyl) oxetane; 3,3-bis-(methyl nitrato methyl) oxetane; 3-methyl nitrato methyl-3-methyl oxetane; 3,3-bis-(azidomethyl) oxetane; and 3-ethyl-3-((2-ethylhexyloxy) methyl) oxetane.

5. The underfill composition as defined in claim 1, wherein the polymer precursor comprises an inorganic backbone.

6. The underfill composition as defined in claim 1, wherein the underfill composition has less that 1 weight percent epoxy-containing material.

7. The underfill composition as defined in claim 1, wherein the underfill composition has less than 1 weight percent cyanate ester-containing material.

8. The underfill composition as defined in claim 1, further comprising a cyanate ester-containing material.

9. The underfill composition as defined in claim 1, wherein the underfill composition further comprises an alcohol and an anhydride; and the alcohol comprises one or more hydroxyl functional groups, and the anhydride comprises one or more cyclic anhydride functional groups; wherein
the anhydride responds to a first stimulus by reacting with the alcohol to increase a molecular weight of the composition or a degree of conversion, while one or more of the oxetane functional groups responds to a second stimulus that is different from the first stimulus to cure.

10. The underfill composition as defined in claim 9, wherein the alcohol and the anhydride are together present in a total amount in a range of from about 5 weight percent to about 60 weight percent of the underfill composition.

11. The underfill composition as defined in claim 1, further comprising a catalyst that catalyzes curing of the polymer precursor in response to a stimulus selected from the group consisting of heat and electromagnetic radiation.

12. The underfill composition as defined in claim 11, wherein the catalyst comprises one or more cationic initiator selected from the group consisting of an onium salt, a Lewis acid, and an alkylation agent.

13. The underfill composition as defined in claim 12, wherein the catalyst comprises one or more material selected from the group consisting of an iodonium salt; an oxonium salt; a sulfonium salt; a sulfoxonium salt; a phosphonium salt; a metal boron acetoacetate; a tris(pentaflurophenyl) boron; and arylsulfonate ester.

14. The underfill composition as defined in claim 11, wherein the underfill composition has less than about 50 percent conversion and is stable in the presence of the catalyst at a temperature in a range of from about 20 degrees Celsius to about 150 degrees Celsius.

15. The underfill composition as defined in claim 1, wherein the polymer precursor cures only at a temperature that is greater than about 150 degrees Celsius.

16. A filled underfill composition comprising a filler and the underfill composition as defined in claim 1.

17. The filled composition as defined in claim 1, wherein the filler comprises a plurality of particles selected from the group consisting of thermally conductive particles, electrically insulating particles, and both thermally conductive particles and electrically insulating particles.

18. The filled composition as defined in claim 17, wherein the thermally conductive particles comprise one or more material selected from the group consisting of siliceous materials, carbonaceous materials, metal hydrates, metal oxides, metal borides, and metal nitrides.

19. The filled composition as defined in claim 17, wherein the electrically insulating particles comprise one or more material selected from the group consisting of siliceous materials, metal hydrates, metal oxides, metal borides, and metal nitrides.

20. The filled underfill composition as defined in claim 17, wherein the filler comprises silica that is both passivated and compatibilized.

21. The filled underfill composition as defined in claim 17, wherein the filler is present in an amount that is greater than about 10 weight percent of the filled underfill composition.

22. The filled underfill composition as defined in claim 15, wherein the filled underfill composition has a room temperature viscosity that is less than about 20000 centipoise when the filler is present in an amount that is greater than about 20 weight percent of the filled underfill composition.

23. An underfill material comprising the filled underfill composition as defined in claim 17, wherein the underfill material cures at a temperature in a range of from about 150 degrees Celsius to about 300 degrees Celsius.

24. A cured underfill layer comprising the underfill material as defined in claim 23.

25. The cured underfill layer as defined in claim 24, wherein the cured underfill layer has a thermal coefficient of expansion that is less than about 50 parts per million per degrees Celsius.

26. The cured underfill layer as defined in claim 22, wherein the cured underfill layer has a modulus that is greater than about 2000 MegaPascals.

27. The cured underfill layer as defined in claim 30, wherein the cured underfill layer has an electrical resistivity that is greater than about 0.001 Ohm centimeters.

28. The cured underfill layer as defined in claim 30, wherein the cured underfill layer is stable at a relative humidity that is greater than about 80 percent and at a temperature greater than about 80 degrees Celsius.

29. An article, comprising:
a chip;
a substrate; and
an underfill material disposed between the chip and the substrate;
wherein the underfill material comprises a filled composition comprising: a filler; and a polymer precursor comprising 4 or more pendant oxetane functional groups; and the polymer precursor comprises greater than about 20 weight percent of the underfill material.

30. The article as defined in claim 27, wherein the underfill material is cured to form a cured underfill layer, and the cured underfill layer secures the chip to the substrate.

31. The article as defined in claim 29, further comprising lead-free electrical interconnects from chip to substrate functionally supported by the cured underfill layer to prevent thermal cycle fatigue.

32. A method comprising:
disposing an underfill material in contact with a surface of a chip; wherein the underfill material comprises a filled composition comprising: a filler; and a polymer precursor comprising 4 or more pendant oxetane functional groups; and the polymer precursor comprises greater than about 20 weight percent of the underfill material;
contacting the chip with a substrate to form an electronic assembly;
heating the electronic assembly to a temperature sufficient to cure the underfill material; and
curing the underfill material.

33. The method as defined in claim 32, wherein the underfill material is cured by heating to a temperature that is greater than about 150 degrees.
